(19) United States
(12) Patent Application Publication
(10) Pub. No.: US 2026/0148757 A1
(43) Pub. Date: May 28, 2026

(54) SEMICONDUCTOR DEVICE AND MANUFACTURING METHOD OF THE SAME, AND ELECTRONIC SYSTEM INCLUDING SEMICONDUCTOR DEVICE

(71) Applicant: Samsung Electronics Co., Ltd., Suwon-si (KR)

(72) Inventors: Jinmyoung LEE, Suwon-si (KR); Hyun-Mook CHOI, Suwon-si (KR)

(73) Assignee: Samsung Electronics Co., Ltd., Suwon-si (KR)

(21) Appl. No.: 19/223,956

(22) Filed: May 30, 2025

(30) Foreign Application Priority Data
Nov. 25, 2024 (KR) 10-2024-0169730

(51) Int. Cl. G11C 5/06; H01L 23/00; H01L 25/18; H10B 41/10; H10B 41/27; H10B 41/35; H10B 41/41; H10B 43/10; H10B 43/27; H10B 43/35; H10B 43/40; H10B 80/00; H10D 80/30

(52) U.S. Cl. CPC G11C 5/063; H10B 41/10; H10B 41/27; H10B 41/35; H10B 41/41; H10B 43/10; H10B 43/27; H10B 43/35; H10B 43/40; H10B 80/00; H10D 80/30; H10W 90/00; H10W 72/934; H10W 80/732; H10W 90/20; H10W 90/24; H10W 90/732; H10W 90/734; H10W 90/752; H10W 90/754; H10W 90/792

(57) ABSTRACT

A semiconductor device including a gate stacking structure, a channel structure, a wiring, an undoped semiconductor layer, and a contact portion may be provided. The gate stacking structure has a first surface and a second surface that are opposite to each other. The gate stacking structure includes a plurality of interlayer insulation layers and a plurality of gate electrodes alternating on each other. The channel structure extends through the gate stacking structure. The wiring is on the first surface of the gate stacking structure. The undoped semiconductor layer is between the first surface of the gate stacking structure and the wiring. The contact portion passes through the undoped semiconductor layer and electrically connects the channel structure and the wiring.

### CROSS-REFERENCE TO RELATED APPLICATION

This application claims priority to and the benefit of Korean Patent Application No. 10-2024-0169730 filed in the Korean Intellectual Property Office on Nov. 25, 2024, the entire contents of which are incorporated herein by reference.

### BACKGROUND

### (a) Field

The present disclosure relates to semiconductor devices, a manufacturing methods of the same, and electronic systems including a semiconductor device.

### (b) Description of the Related Art

In an electronic system implementing a data storage, a semiconductor device capable of storing high-capacity data is in demand. Accordingly, a method for increasing a data storage capacity of a semiconductor device is being researched. For example, as one method for increasing a data storage capacity of a semiconductor device, a semiconductor device including three-dimensionally arranged memory cells instead of two-dimensionally arranged memory cells has been proposed.

### SUMMARY

Some example embodiments of the present disclosure provide semiconductor devices, a manufacturing methods of the same capable of improving reliability and/or productivity, and electronic systems including a semiconductor device.

According to an example embodiment, a semiconductor device may include a gate stacking structure including a first surface and a second surface that are opposite to each other, the gate stacking structure including a plurality of interlayer insulation layers and a plurality of gate electrodes alternating on each other, a channel structure extending through the gate stacking structure, a wiring on the first surface of the gate stacking structure, an undoped semiconductor layer between the first surface of the gate stacking structure and the wiring, and a contact portion passing through the undoped semiconductor layer and electrically connecting the channel structure and the wiring.

According to an example embodiment, a semiconductor device may include a gate stacking structure including a first surface and a second surface that are opposite to each other, the gate stacking structure including a plurality of interlayer insulation layers and a plurality of gate electrodes alternating on each other, a channel structure including a penetration portion and an expanded portion, the penetration portion extending through the gate stacking structure, the expanded portion being on the first surface of the gate stacking structure and having a width or an area greater than a width or an area of the penetration portion, a wiring on the first surface of the gate stacking structure, and a contact portion corresponding to the channel structure and electrically connecting the channel structure and the wiring, the contact portion having a width or an area greater than a width or an area of the penetration portion of the channel structure.

According to an example embodiment, an electronic system may include a main substrate, a semiconductor device on the main substrate, and a controller electrically connected to the semiconductor device on the main substrate, wherein the semiconductor device includes a gate stacking structure including a first surface and a second surface that are opposite to each other, the gate stacking structure including a plurality of interlayer insulation layers and a plurality of gate electrodes alternating on each other, a channel structure extending through the gate stacking structure, a wiring on the first surface of the gate stacking structure, an undoped semiconductor layer between the first surface of the gate stacking structure and the wiring, and a contact portion passing through the undoped semiconductor layer and electrically connecting the channel structure and the wiring.

According to an example embodiment, a manufacturing method of a semiconductor device may include forming a preliminary structure including a semiconductor substrate and a stacking structure, the semiconductor substrate including a guide pattern, the stacking structure being on the semiconductor substrate and including a plurality of sacrificial insulation layers and a plurality of interlayer insulation layers, forming a channel structure passing through the stacking structure to correspond to the guide pattern in a plan view, forming a gate stacking structure by replacing the plurality of sacrificial insulation layers with a plurality of gate electrodes, removing the guide pattern to define a through hole, and forming a wiring portion including a contact portion and a wiring electrically connected to the contact portion, the contact portion being in the through hole.

According to an example embodiment, a contact portion (e.g., a bit line contact) may be formed by a self-alignment process using a guide pattern. Accordingly, the contact portion may be stably formed at a desired position by an easy process. Accordingly, reliability and/or productivity of a semiconductor device may be improved.

### BRIEF DESCRIPTION OF THE DRAWINGS

FIG. 1 is a partial cross-sectional view that schematically illustrates a semiconductor device according to an example embodiment.

FIG. 2 is an enlarged partial cross-sectional view that illustrates an example of a channel structure included in the semiconductor device illustrated in FIG. 1.

FIG. 3 is a plan view that schematically illustrates a cell array region of the semiconductor device illustrated in FIG. 1.

FIG. 4 is an enlarged partial cross-sectional view of a portion A in FIG. 1.

FIG. 5 to FIG. 16 are cross-sectional views that illustrate a manufacturing method of a semiconductor device according to an example embodiment.

FIG. 17 is a cross-sectional view that illustrates a part of a manufacturing method of a semiconductor device according to a modified example embodiment.

FIG. 18 and FIG. 19 are cross-sectional views that illustrate a part of a manufacturing method of a semiconductor device according to a modified example embodiment.

FIG. 20 is a cross-sectional view that illustrates a part of a manufacturing method of a semiconductor device according to a modified example embodiment.

FIG. 21 is a partial cross-sectional view that illustrates a semiconductor device according to an example embodiment.

FIG. 22 to FIG. 28 are cross-sectional views that illustrate a manufacturing method of a semiconductor device according to an example embodiment.

FIG. 29 is a plan view that schematically illustrates a semiconductor device according to an example embodiment.

FIG. 30 is an enlarged plan view of a portion C in FIG. 29.

FIG. 31 is a partial cross-sectional view taken along a line D-D′ and a line E-E′ in FIG. 29.

FIG. 32 to FIG. 38 illustrate a manufacturing method of a semiconductor device according to an example embodiment.

FIG. 39 is a view that schematically illustrates an electronic system including a semiconductor device according to an example embodiment

FIG. 40 is a perspective view that schematically illustrates an electronic system including a semiconductor device according to an example embodiment.

FIG. 41 is a cross-sectional view that schematically illustrates a semiconductor package according to an example embodiment.

### DETAILED DESCRIPTION

Example embodiments of the present disclosure will be described more fully hereinafter with reference to the accompanying drawings for those skilled in the art to which the present disclosure pertains to easily practice the present disclosure. The present disclosure may be implemented in various different forms and is not limited to the example embodiment provided herein.

A portion unrelated to the description is omitted in order to clearly describe the present disclosure, and the same or similar components are denoted by the same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration

It will be understood that when a component such as a portion, a region, a member, a unit, a layer, a film, a substrate, or the like is referred to as being “on” another component, it may be directly on another component or an intervening component may also be present. In contrast, when a component is referred to as being “directly on” another component, there is no intervening component. Further, when a component is referred to as being “on” or “above” a reference component, a component may be disposed on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

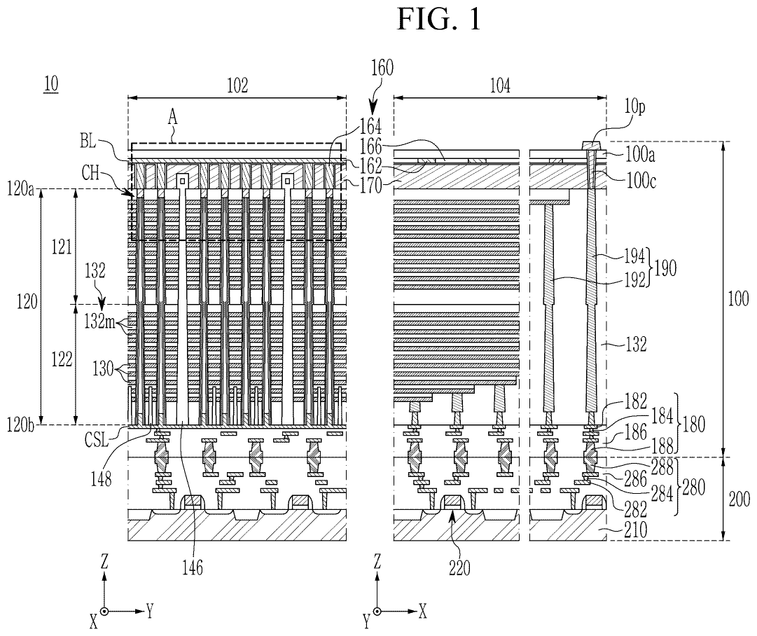

Hereinafter, referring to FIG. 1 to FIG. 16, a semiconductor device according to an example embodiment and a manufacturing method of the same will be described in detail.

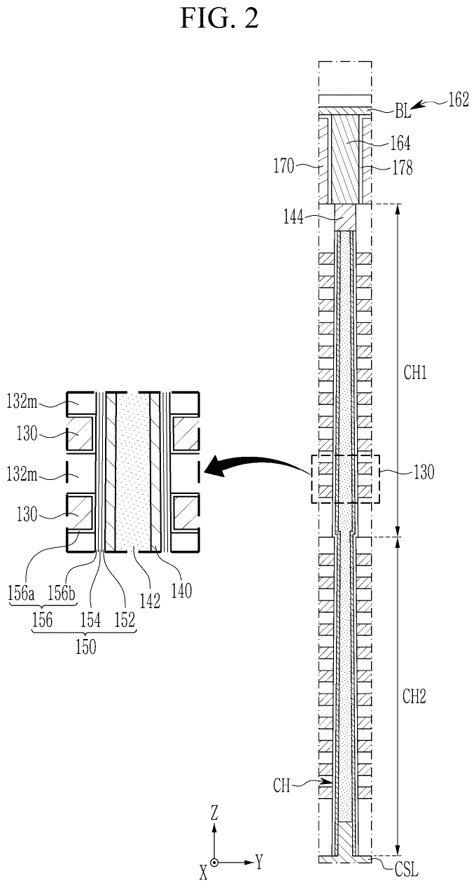

FIG. 1 is a partial cross-sectional view that schematically illustrates a semiconductor device 10 according to an example embodiment. FIG. 2 is an enlarged partial cross-sectional view that illustrates an example of a channel structure CH included in the semiconductor device 10 illustrated in FIG. 1. For a clear understanding, FIG. 1 illustrates a gate contact portion 192 and an input/output connection wiring 194 together, but positions of the gate contact portion 192 and the input/output connection wiring 194 may be variously modified.

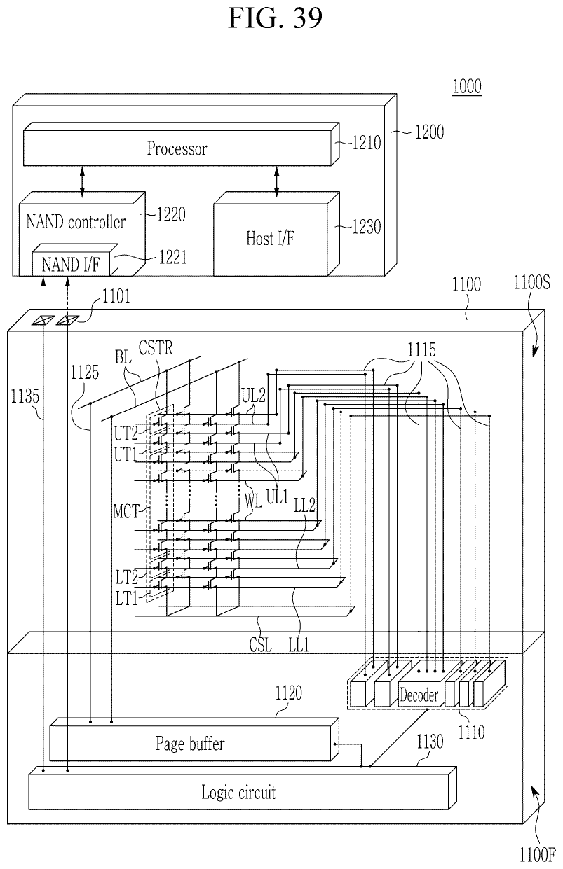

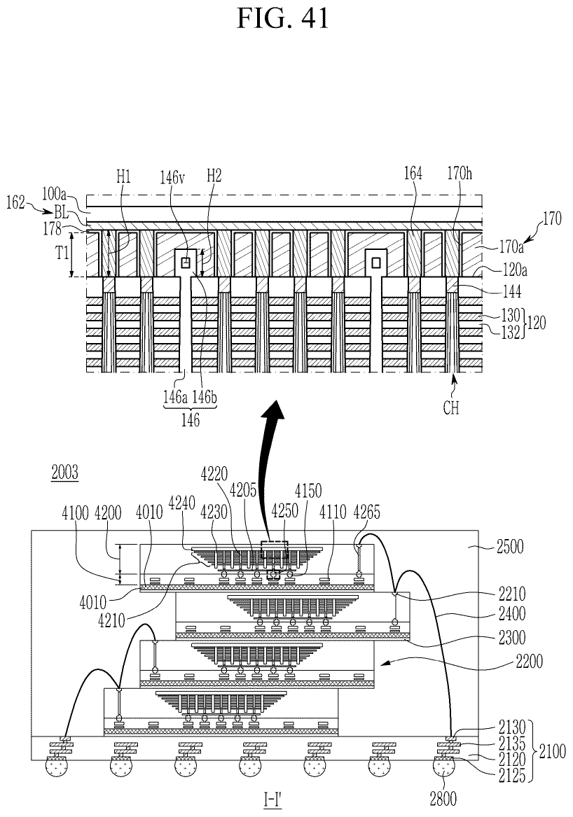

Referring to FIG. 1 and FIG. 2, a semiconductor device 10 according to an example embodiment may include a cell region 100 that includes a memory cell structure and a circuit region 200 that includes a peripheral circuit structure configured to control an operation of the memory cell structure. For example, the circuit region 200 and the cell region 100 may correspond to a first structure 1100F and a second structure 1100S of a semiconductor device 1100 included in an electronic system 1000 illustrated in FIG. 39, respectively. For example, the circuit region 200 and the cell region 100 may be portions including a first structure 4100 and a second structure 4200 of a semiconductor chip 2200 illustrated in FIG. 41, respectively.

In an example embodiment, the semiconductor device 10 may be a bonding semiconductor device formed by separately forming the cell region 100 and the circuit region 200 and bonding the cell region 100 to the circuit region 200. For example, the cell region 100 may be bonded to the circuit region 200 by hybrid bonding such as a chip to chip (C2C) bonding process, a chip-to-wafer bonding process, or a wafer-to-wafer bonding process. When the cell region 100 and the circuit region 200 are formed through separate processes, the cell region 100 may be reduced or prevented from affecting the circuit region 200 in a process of forming the cell region 100. For example, the semiconductor device 10 may be a bonding vertical NAND (BV NAND).

In an example embodiment, the cell region 100 may be disposed on the circuit region 200. Accordingly, an area corresponding to the circuit region 200 does not need to be separately secured from the cell region 100. Therefore, an area of the semiconductor device 10 may be reduced.

The cell region 100 may include a gate stacking structure 120, a channel structure CH, a wiring portion (e.g., a first wiring portion 160, a second wiring portion 180, and/or a through connecting portion 190).

The cell region 100 may include a cell array region 102 and a connection region 104. The cell region 100 may include the gate stacking structure 120 and the channel structure CH disposed in at least the cell array region 102 as a memory cell structure. A structure that connects the memory cell structure to the circuit region 200 or an external circuit may be disposed in the cell array region 102 and/or the connection region 104.

The gate stacking structure 120 may include cell insulation layers 132 (e.g., interlayer insulation layers 132m) and gate electrodes 130 alternately stacked to each other. The channel structure CH may extend to pass through the gate stacking structure 120. For example, the channel structure CH may extend in a thickness direction of the semiconductor device 10 or a vertical direction (e.g., a Z-axis direction in the drawings).

The gate stacking structure 120 may have a first surface 120a and a second surface 120b opposite to each other. The second surface 120b of the gate stacking structure 120 may be a facing surface that faces the circuit region 200, and the first surface 120a of the gate stacking structure 120 may be an opposite surface that is opposite to the circuit region 200.

The gate electrode 130 may include any of various conductive materials. For example, the gate electrode 130 may include or be formed of a metal material (e.g., tungsten (W), titanium (Ti), tantalum (Ta), copper (Cu), aluminum (Al), cobalt (Co), ruthenium (Ru), or the like), polycrystalline silicon, metal nitride (e.g., tungsten nitride(WN), titanium nitride (TiN), tantalum nitride (TaN), or the like), or a combination thereof. The cell insulation layer 132 may include any of various insulating materials. For example, the interlayer insulation layer 132m may include or be formed of silicon oxide, silicon nitride, silicon oxynitride, a low dielectric constant material having a lower dielectric constant than silicon oxide, or a combination thereof.

The channel structure CH may include a channel layer 140, and a gate dielectric layer 150 on the channel layer 140 between the gate electrode 130 and the channel layer 140. The gate dielectric layer 150 between the gate electrode 130 and the channel layer 140 may include a tunneling layer 152, a charge storage layer 154, and a blocking layer 156 sequentially on the channel layer 140.

The channel structure CH may further include a core insulation layer 142 at an inside of the channel layer 140. In some example embodiments, the core insulation layer 142 may be omitted. The channel structure CH may further include a channel pad 144 on the channel layer 140 and/or the core insulation layer 142.

In an example embodiment, the channel pad 144 (e.g., a first channel pad) may be disposed at a first end of the channel structure CH that is adjacent to the first surface 120a of the gate stacking structure 120. The first channel pad may be disposed on the core insulation layer 142 (on an upper surface of the core insulation layer 142 in the FIG. 2) to be electrically connected to the channel layer 140, and may be electrically connected to a first contact portion 164 (e.g., a bit line contact) of the first wiring portion 160.

For example, a first end of the channel layer 140, the core insulation layer 142, and/or the gate dielectric layer 150 that is adjacent to the first surface 120a of the gate stacking structure 120 may be spaced apart from the first surface 120a of the gate stacking structure 120, and the first channel pad may be disposed between the first end of the channel layer 140, the core insulation layer 142, and/or the gate dielectric layer 150 and the first surface 120a of the gate stacking structure 120.

In an example embodiment, a channel pad (e.g., a second channel pad) may be disposed at a second end of the channel structure CH that is adjacent to the second surface 120b of the gate stacking structure 120. The channel pad (e.g., the second channel pad) may be formed of a portion (e.g., a protrusion portion) of a common source electrode CSL. The second channel pad may be disposed on the core insulation layer 142 (on a lower surface of the core insulation layer 142 in the FIG. 2) to be electrically connected to the channel layer 140, and may be formed of a portion of the common source electrode CSL. The second channel pad may be regarded as a portion of the channel structure CH or a portion of the common source electrode CSL. However, example embodiments are not limited thereto. For example, the second channel pad that is disposed at the second end of the channel structure CH may be separately formed from the common source electrode CSL or may include a material different from a material of the common source electrode CSL.

For example, a second end of the channel layer 140, the core insulation layer 142 and/or the gate dielectric layer 150 that is adjacent to the second surface 120b of the gate stacking structure 120 may be spaced apart from the second surface 120b of the gate stacking structure 120, and the second channel pad may be disposed between the second end of the channel layer 140, the core insulation layer 142, and/or the gate dielectric layer 150 and the second surface 120b of the gate stacking structure 120.

Each channel structure CH may form one memory cell string, and a plurality of channel structures CH may be spaced apart from each other while forming rows and columns in a plan view. For example, a plurality of channel structures CH may be disposed to form any of various shapes such as a lattice shape, a zigzag shape, or the like in a plan view. The channel structure CH may have a pillar shape. For example, the channel structure CH may have a planar shape of a circular shape, but example embodiments are not limited thereto and the channel structure CH may have any of various planar shapes of an oval shape, a polygonal shape, or the like. For example, in a cross-sectional view, the channel structure CH may have an inclined side surface such that a width of the channel structure CH decreases toward the first surface 120a of the gate stacking structure 120 due to a relatively high aspect ratio. However, example embodiments are not limited thereto, and an arrangement, a structure, a shape, or the like of the channel structure CH may be variously modified.

The channel layer 140 may include a semiconductor material (e.g., polycrystalline silicon). The core insulation layer 142 may include any of various insulating materials. For example, the core insulation layer 142 may include or be formed of silicon oxide, silicon nitride, silicon oxynitride, or a combination thereof. The channel pad 144 may include a conductive material (e.g., polycrystalline or single-crystalline silicon doped with a dopant).

The tunneling layer 152 may include an insulating material that is capable of tunneling a charge (e.g., silicon oxide, silicon oxynitride, or the like). The charge storage layer 154 may be used as a data storage region, and the charge storage layer 154 may include polycrystalline silicon, silicon nitride, or the like. The blocking layer 156 may include an insulating material that is capable of blocking or preventing an undesirable flow of charge into the gate electrode 130. The blocking layer 156 may include, for example, silicon oxide, silicon nitride, silicon oxynitride, a high dielectric constant material having a higher dielectric constant than silicon oxide, or a combination thereof. In an example embodiment, the blocking layer 156 may include a first blocking layer 156a that includes a portion horizontally extending on the gate electrode 130, and a second blocking layer 156b that vertically extends between the first blocking layer 156a and the charge storage layer 154.

However, example embodiments are not limited to a material, a structures, or the like of the channel layer 140, the core insulation layer 142, the core insulation layer 142, or the gate dielectric layer 150.

In an example embodiment, the gate stacking structure 120 may include a plurality of gate stacking portions 121 and 122 that are sequentially stacked. Thereby, a number of stacked gate electrodes 130 may increase and thus a number of memory cells may increase with a stable structure. In FIG. 1, it is illustrated as an example that the gate stacking structure 120 includes first and second gate stacking portions 121 and 122. However, example embodiments are not limited thereto, and the gate stacking structure 120 may include one gate stacking portion or three or more gate stacking portions.

When the plurality of gate stacking portions 121 and 122 are provided as in the above, the channel structure CH may include a plurality of channel portions CH1 and CH2 that pass through the plurality of gate stacking portions 121 and 122, respectively. The plurality of channel portions CH1 and CH2 may be connected to each other. In a cross-sectional view, each of the plurality of channel portions CH1 and CH2 may have an inclined side surface such that a width of each of the plurality of channel portions CH1 and CH2 decreases toward the first surface 120a of the gate stacking structure 120 due to a relatively high aspect ratio. A bent portion due to a difference in widths of the plurality of channel portions CH1 and CH2 may be provided at a connection portion of the plurality of channel portions CH1 and CH2. In some example embodiments, the plurality of channel portions CH1 and CH2 may have an inclined side surface that continuously extends without the bent portion. In FIG. 2, it is illustrated as an example that each of the gate dielectric layer 150, the channel layer 140, and the core insulation layer 142 of the plurality of channel portions CH1 and CH2 continuously extends to have an integral structure. In some example embodiments, gate dielectric layers 150, channel layers 140, and core insulation layers 142 of a plurality of channel portions CH1 and CH2 may be separately formed and be electrically connected to each other. In some example embodiments, a separate channel pad may be additionally disposed at the connection portion of the plurality of channel portions CH1 and CH2. As such, example embodiments are not limited to a shape of the plurality of channel portions CH1 and CH2 as illustrated in FIGS. 1 and 2.

In an example embodiment, the gate stacking structure 120 may be divided into a plurality of portions in a plan view by a separation structure 146 that passes through the gate stacking structure 120. A separation pattern 148 may be disposed to be adjacent to the second surface 120b of the gate stacking structure 120. In a plan view, the separation structure 146 and/or the separation pattern 148 may extend in a first direction (an X-axis direction in the drawings). A plurality of separation structures 146 and/or a plurality of separation patterns 148 may be spaced apart from each other at desired (or alternatively, predetermined) intervals in a second direction (a Y-axis direction in the drawings) that intersects (e.g., is perpendicular to) the first direction.

In a plan view, by the separation structure 146, a plurality of gate stacking structures 120 may extend in the first direction (the X-axis direction in the drawings) and may be spaced apart from each other at desired (or alternatively, predetermined) intervals in the second direction (the Y-axis direction in the drawings) that intersects the first direction. The gate stacking structure 120 divided by the separation structure 146 may form one memory cell block. However, example embodiments are not limited thereto, and a range of the memory cell block is not limited thereto.

For example, the separation structure 146 may pass through the gate stacking structure 120, and the separation pattern 148 may separate one or a part of the plurality of gate electrodes 130. The separation pattern 148 may be disposed between the separation structures 146. In a cross-sectional view, the separation structure 146 or the separation pattern 148 may extend to pass through the gate stacking structure 120 in the thickness direction of the semiconductor device 10 or the vertical direction (the Z-axis direction in the drawings).

For example, in a cross-sectional view, the separation structure 146 may have an inclined side surface such that a width of the separation structure 146 decreases toward the first surface 120a of the gate stacking structure 120 due to a relatively high aspect ratio, but example embodiments are not limited thereto. A side surface of the separation structure 146 may be parallel to the thickness direction of the semiconductor device 10 or the vertical direction (the Z-axis direction in the drawings) or may have a bent portion at the connection portion of the plurality of gate stacking portions 121 and 122.

The separation structure 146 and/or the separation pattern 148 may include any of various insulating materials. For example, the separation structure 146 or the separation pattern 148 may include or be formed of an insulating material such as silicon oxide, silicon nitride, or silicon oxynitride. However, example embodiments are not limited thereto, and a structure, a shape, or the like of the separation structure 146 or the separation pattern 148 may be variously modified.

The connection region 104 and the wiring portion may be provided to connect the gate stacking structure 120 and the channel structure CH in the cell array region 102 to the circuit region 200 or the external circuit. The connection region 104 may be disposed at a periphery of the cell array region 102 and a portion of the wiring portion may be disposed in the connection region 104.

In an example embodiment, the wiring portion may include a member that electrically connects the gate electrode 130 and/or the channel structure CH to the circuit region 200 or the external circuit. The wiring portion may include the first wiring portion 160, the second wiring portion 180, and the through connecting portion 190. The first wiring portion 160 may disposed on the first surface 120a of the gate stacking structure 120. The second wiring portion 180 may be disposed on the second surface 120b of the gate stacking structure 120 (e.g., between the second surface 120b of the gate stacking structure 120 and the circuit region 200). The through connecting portion 190 may be disposed in the connection region 104.

In an example embodiment, the first wiring portion 160 may include a bit line BL, the second wiring portion 180 may include a common source electrode CSL and a bonding structure 188, and the through connecting portion 190 may include a gate contact portion 192 and an input/output connection wiring 194.

For example, the first wiring portion 160 may include a first wiring 162, a first contact portion 164, and a first insulation layer 166. The first wiring 162 may be disposed on the first surface 120a of the gate stacking structure 120. The first contact portion 164 may electrically connect the channel structure CH (e.g., the channel pad 144) and the first wiring 162. The first insulation layer 166 may be provided for electrical insulation of the first wiring portion 160. In an example embodiment, an undoped semiconductor layer 170 may be disposed on the first surface 120a of the gate stacking structure 120 between the first surface 120a of the gate stacking structure 120 and the first wiring 162, and the first contact portion 164 may pass through the undoped semiconductor layer 170 and electrically connect the channel structure CH (e.g., the channel pad 144) and the first wiring 162.

In an example embodiment, the first wiring 162 may include the bit line BL, and the first contact portion 164 may include a bit line contact. This will be described later in more detail. The first wiring 162 may further include a connection wiring that is electrically connected to the common source electrode CSL, the gate contact portion 192, and/or the input/output connection wiring 194, or the like. In an example embodiment, the undoped semiconductor layer 170 may be used for a mask layer for forming the first contact portion 164 or a layer for forming the first contact portion 164 by a self-alignment process. This will be described later in more detail.

The undoped semiconductor layer 170 may be electrically insulated from the first wiring 162 and the first contact portion 164 not to contribute to electrical connection. The undoped semiconductor layer 170 may include an undoped material to improve an insulation property of the first wiring 162 and/or the first contact portion 164. However, example embodiments are not limited thereto. A layer that includes a dopant and is not electrically connected to the first wiring 162 and/or the first contact portion 164 may be regarded as a layer corresponding to the undoped semiconductor layer 170 according to an example embodiment.

The first wiring 162 or the first contact portion 164 of the first wiring portion 160 may include any of various conductive materials, and the first insulation layer 166 of the first wiring portion 160 may include any of various insulating materials. For example, the bit line BL or the first contact portion 164 (e.g., the bit line contact) may include or be formed of a metal material (e.g., tungsten (W), titanium (Ti), tantalum (Ta), copper (Cu), aluminum (Al), cobalt (Co), ruthenium (Ru), or the like), polycrystalline silicon, metal nitride (e.g., tungsten nitride (WN), titanium nitride (TiN), tantalum nitride (TaN), or the like), or a combination thereof.

For a clear understanding and simple illustration, in the drawings, it is illustrated as an example that the first wiring portion 160 includes one first wiring 162 (e.g., the bit line BL), but example embodiments are not limited thereto. Another first wiring that is disposed at a layer different from the bit line BL or the first wiring 162 and is electrically connected to the bit line BL or the first wiring 162 and/or another first contact portion that connects a plurality of first wirings may be further included. An outer insulation layer 100a may be disposed on the first wiring portion 160.

For example, the second wiring portion 180 may include a second wiring 182, a second contact portion 184, a bonding structure 188, and a second insulation layer 186. The second wiring 182 may be disposed on the second surface 120b of the gate stacking structure 120. The second contact portion 184 may be electrically connected to the second wiring 182. The bonding structure 188 may be disposed in a portion facing the circuit region 200. The second insulation layer 186 may be provided for electrical insulation of the second wiring portion 180.

In an example embodiment, the second wiring 182 may include the common source electrode CSL that is electrically connected to the channel structure CH. The common source electrode CSL may be electrically connected to the channel structure CH in a portion that is adjacent to the second surface 120b of the gate stacking structure 120. In an example embodiment, the common source electrode CSL may include a horizontal portion and a protrusion portion. The horizontal portion may be disposed on the second surface 120b of the gate stacking structure 120 in the cell array region 102. The protrusion portion may protrude from the horizontal portion. The protrusion portion of the common source electrode CSL may form the second channel pad of the channel structure CH. Thereby, the common source electrode CSL that is electrically connected to the channel structure CH in a portion that is adjacent to the second surface 120b of the gate stacking structure 120 may be easily formed. However, example embodiments are not limited thereto. The horizontal portion and the protrusion portion of the common source electrode CSL may be separately formed, and/or an additional structure (e.g., a contact via) that connects the channel pad of the channel structure CH and the horizontal portion of the common source electrode CSL may be further included. Various other example embodiments are possible.

The second wiring 182 may further include a connection wiring that is electrically connected to the common source electrode CSL, the gate contact portion 192, the input/output connection wiring 194, or the like. The second insulation layer 186 of the second wiring portion 180 may include a second bonding insulation layer at a periphery of the bonding structure 188 in a portion that faces the circuit region 200.

The second wiring 182, the second contact portion 184, or the bonding structure 188 of the second wiring portion 180 may include any of various conductive materials, and the second insulation layer 186 of the second wiring portion 180 may include any of various insulating materials.

The through connecting portion 190 may include the gate contact portion 192 and the input/output connection wiring 194.

In an example embodiment, the plurality of gate electrodes 130 may extend in the first direction (the X-axis direction in the drawings) in the connection region 104, and extension lengths of the plurality of gate electrodes 130 in the connection region 104 may be sequentially decrease far away from the first surface 120a of the gate stacking structure 120. For example, a plurality of gate electrodes 130 may have a stair shape in one or a plurality of directions in the connection region 104. In the connection region 104, a plurality of gate contact portions 192 may pass through the cell insulation layer 132 and may be electrically connected to the plurality of gate electrodes 130 that extend in the connection region 104, respectively.

In an example embodiment, the undoped semiconductor layer 170 may be disposed between the gate stacking structure 120 and the first wiring 162 in the connection region 104. However, example embodiments are not limited thereto, and various other example embodiments are possible. For example, the undoped semiconductor layer 170 may not be disposed between the gate stacking structure 120 and the first wiring 162 in the connection region 104.

The input/output connection wiring 194 may be electrically connected to an input/output pad 10p included in the cell region 100. In the drawings, it is illustrated as an example that the input/output connection wiring 194 is electrically connected to the input/output pad 10p through an input/output contact portion 100c that passes through the undoped semiconductor layer 170 and the outer insulation layer 100a. An insulation layer may be disposed between the undoped semiconductor layer 170 and the input/output contact portion 100c and/or between the outer insulation layer 100a and the input/output contact portion 100c to electrically insulate the input/output contact portion 100c from the undoped semiconductor layer 170 and/or the outer insulation layer 100a. However, example embodiments are not limited thereto, and the input/output pad 10p and the input/output connection wiring 194 may be electrically connected by any of various structures. The input/output connection wiring 194 may be electrically connected to a part of the bonding structures 188 of the second wiring portion 180. In some example embodiments, an additional input/output pad electrically connected to the circuit region 200 may be provided.

The circuit region 200 may be electrically connected to the cell region 100, and may include a substrate 210, a circuit element 220, the circuit wiring portion 280. The substrate 210 may be a semiconductor substrate including a semiconductor material. For example, the substrate 210 may be a semiconductor substrate including or being formed of a semiconductor material or may be a semiconductor substrate in which a semiconductor layer is on a base substrate. For example, the substrate 210 may include or be formed of single-crystalline or polycrystalline silicon, epitaxial silicon, germanium, silicon-germanium, silicon on insulator (SOI), germanium on insulator (GOI), or the like.

The circuit element 220 on the substrate 210 may include any of various circuit elements and constitute a periphery circuit structure that controls an operation of the memory cell structure in the cell region 100. For example, the circuit element 220 may constitute the peripheral circuit structure such as a decoder circuit 1110 (refer to FIG. 39), a page buffer 1120 (refer to FIG. 39), a logic circuit 1130 (refer to FIG. 39), or the like.

The circuit element 220 may include, for example, a transistor, but example embodiments are not limited thereto. For example, the circuit element 220 may include not only an active element such as the transistor or the like but also a passive element such as a capacitor, a resistor, an inductor, or the like.

The circuit wiring portion 280 on the substrate 210 may be electrically connected to the circuit element 220. In an example embodiment, the circuit wiring portion 280 may include a plurality of wiring layers 282 that are spaced apart from each other while interposing an insulation layer 286 therebetween and are electrically connected by a contact via 284 to form a desired path, and a bonding structure 288 that is electrically connected to the plurality of wiring layers 282. The wiring layer 282, the contact via 284, or the bonding structure 288 of the circuit wiring portion 280 may include any of various conductive materials, and the insulation layer 286 of the circuit wiring portion 280 may include any of various insulating materials.

In an example embodiment, the cell region 100 and the circuit region 200 may be bonded to each other by hybrid bonding. For example, the cell region 100 and the circuit region 200 may be bonded to each other by hybrid bonding including metal bonding between the bonding structures 188 and 288 and including insulation-layer bonding between bonding insulation layers at a periphery of the bonding structures 188 and 288.

For example, the bonding structure 188 of the cell region 100 and/or the bonding structure 288 of the circuit region 200 may include or be formed of at least one of copper, aluminum, tungsten, nickel, gold, tin, manganese, cobalt, titanium, tantalum, ruthenium or beryllium or may include or be formed of an alloy including at least one of the above materials. For example, the bonding structure 188 of the cell region 100 and the bonding structure 288 of the circuit region 200 may include copper so that the cell region 100 and the circuit region 200 may be bonded (e.g., directly bonded) to each other by copper-to-copper bonding.

For example, the bonding insulation layer of the cell region 100 and the bonding insulation layer of the circuit region 200 may include a same insulating material at least at an insulation boding surface. For example, the bonding insulation layer of the cell region 100 and the bonding insulation layer of the circuit region 200 may include silicon carbonitride at least at a bonding surface. However, example embodiments are not limited thereto. The bonding insulation layer of the cell region 100 and/or the bonding insulation layer of the circuit region 200 may include a material same as or different from a material of the cell insulation layer 132 of the cell region 100 or the insulation layer 286 the circuit region 200.

In an example embodiment, by the wiring portion of the cell region 100 and the circuit wiring portion 280, the bit line BL connected to the channel structure CH and/or the gate electrode 130 may be electrically connected to the circuit element 220 of the circuit region 200.

In FIG. 1, it is illustrated as an example that the gate contact portion 192 and/or the input/output connection wiring 194 have an inclined side surface such that a width of the gate contact portion 192 and/or the input/output connection wiring 194 decreases toward the first surface 120a of the gate stacking structure 120 due to an aspect ratio and a bent portion is provided at the connection portion of the plurality of gate stacking portions 121 and 122 in a cross-sectional view. However, example embodiments are not limited thereto. In some example embodiments, the gate contact portion 192 and/or the input/output connection wiring 194 may not include the bent portion at the connection portion between the plurality of gate stacking portions 121 and 122.

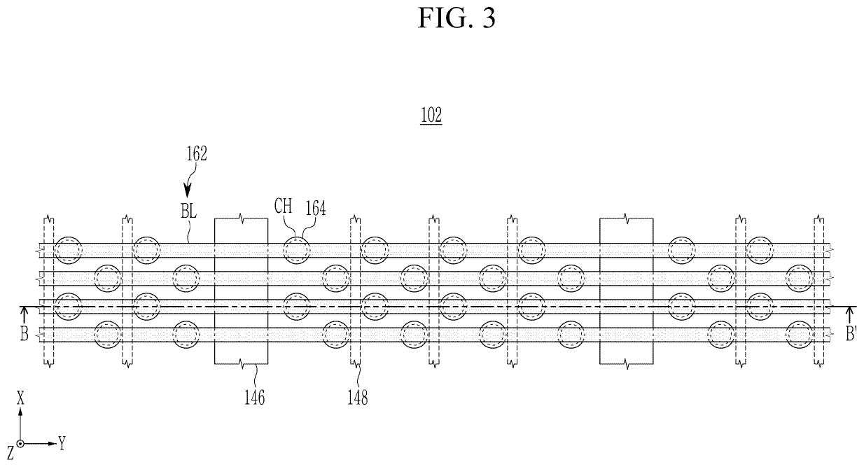

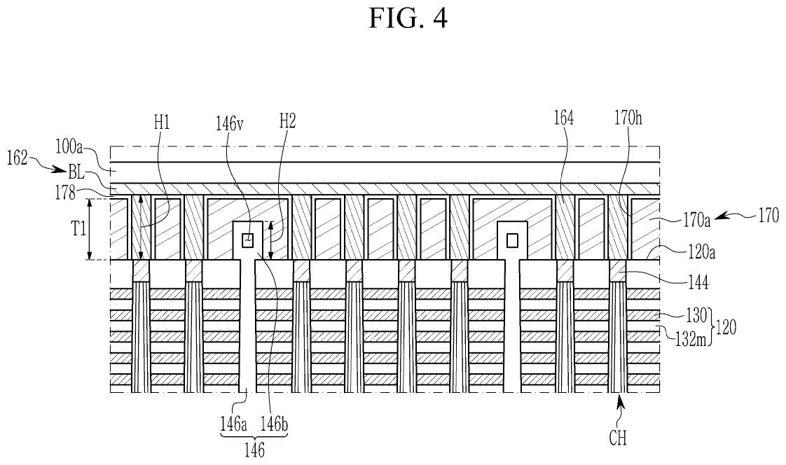

Referring to FIG. 3 and FIG. 4, the first wiring portion 160 and the undoped semiconductor layer 170 according to an example embodiment will be described in more detail.

FIG. 3 is a plan view that schematically illustrates the cell array region 102 of the semiconductor device 10 illustrated in FIG. 1. FIG. 4 is an enlarged partial cross-sectional view of a portion A in FIG. 1. FIG. 4 illustrates a cross-sectional view taken along a line B-B'in FIG. 3. For a clear understanding and simple illustration, FIG. 3 mainly illustrates the channel structure CH, the first contact portion 164, the bit line BL, the separation structure 146, and the separation pattern 148.

Referring to FIG. 3 and FIG. 4, in an example embodiment, the bit line BL may extend in the second direction (the Y-axis direction in the drawings) that intersects the first direction (the X-axis direction in the drawings) in which the gate electrode 130 extends. A plurality of bit lines BL may be spaced apart from each other at regular intervals in the first direction. In an example embodiment, in a plan view, one bit line BL may overlap each of corresponding channel structures CH.

Each channel structure CH may be electrically connected to the bit line BL that overlaps each channel structure CH in a plan view through the first contact portion 164 (e.g., the bit line contact). For example, the channel structure CH (e.g., the channel pad 144) and the bit line BL may be electrically connected to each other through the first contact portion 164. For example, one surface of the first contact portion 164 that is adjacent to the channel pad 144 may be in contact with the channel pad 144, and the other surface of the first contact portion 164 that is adjacent to the bit line BL may be in contact with the bit line BL. However, example embodiments are not limited thereto. In some example embodiments, an insulation layer may be further included between the first contact portion 164 and the bit line BL, and an additional contact via that passes through the insulation layer to connect the first contact portion 164 and the bit line BL may be further included.

Between the first surface 120a of the gate stacking structure 120 and the first wiring 162 (e.g., at least between the first surface 120a of the gate stacking structure 120 and the bit line BL), the undoped semiconductor layer 170 may be disposed.

In an example embodiment, the undoped semiconductor layer 170 may include a first portion 170a. The first portion 170a may be disposed between the first surface 120a of the gate stacking structure 120 and the first wiring 162 (e.g., at least between the first surface 120a of the gate stacking structure 120 and the bit line BL) and may have a layered shape. The first portion 170a may include a through hole 170h in a portion overlapping the channel structure CH in a plan view. Having a layered shape may refer to have a shape that extends horizontally in a portion other than the through hole 170h. For example, the first portion 170a may have a layered shape to be connected in a portion other than a plurality of through holes 170h that correspond to the plurality of channel structures CH, respectively, to have an integral structure. Accordingly, the plurality of through holes 170h may be disposed inside the first portion 170a.

The undoped semiconductor layer 170 may be electrically insulated from the first contact portion 164 and the bit line BL by a liner layer 178. For example, the liner layer 178 may include a side surface portion and a planar portion. The side surface portion may be disposed between the first portion 170a and the first contact portion 164 (e.g., between a side surface of the first portion 170a and a side surface of the first contact portion 164). The planar portion may be disposed between the first portion 170a and the first wiring 162 (e.g., between an upper surface of the first portion 170a and the lower surface of the first wiring 162). For example, the liner layer 178 may include or be formed of silicon oxide, silicon nitride, silicon oxynitride, a low dielectric constant material, or the like. However, example embodiments are not limited thereto, and a material of the liner layer 178 may be variously modified.

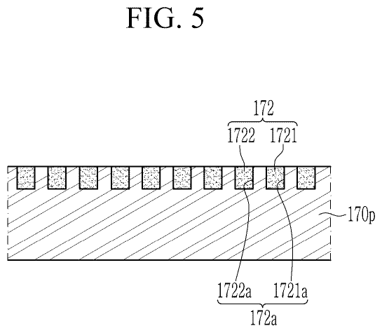

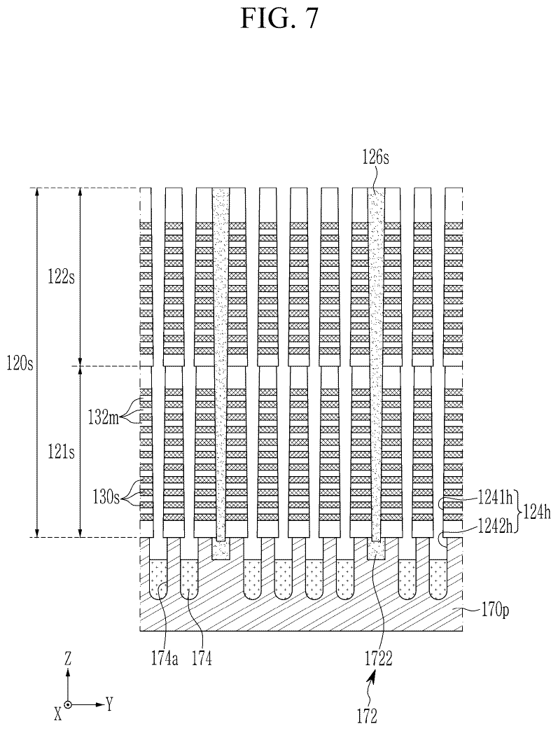

In an example embodiment, the first contact portion 164 may be formed through a self-alignment process using the undoped semiconductor layer 170 (e.g., the first portion 170a). For example, in a manufacturing method of the semiconductor device 10, a guide pattern 174 (refer to FIG. 7) may be formed in a portion of a semiconductor substrate 170p (refer to FIG. 5) that corresponds to at least a portion of the first contact portion 164, the through hole 170h may be formed through removing the guide pattern 174, and the liner layer 178 and the first contact portion 164 may be formed in the through hole 170h. Accordingly, the first contact portion 164 may be formed by a self-alignment in a portion where the guide pattern 174 was disposed. The guide pattern 174 may be configured to provide a space where at least a portion of the first contact portion 164 is disposed. The guide pattern 174 may be referred to as a place holder, a position indication pattern, a self-alignment pattern, a preliminary pattern for a contact portion, or the like. A portion of the semiconductor substrate 170p located other than the first contact portion 164 may remain and form the first portion 170a of the undoped semiconductor layer 170.

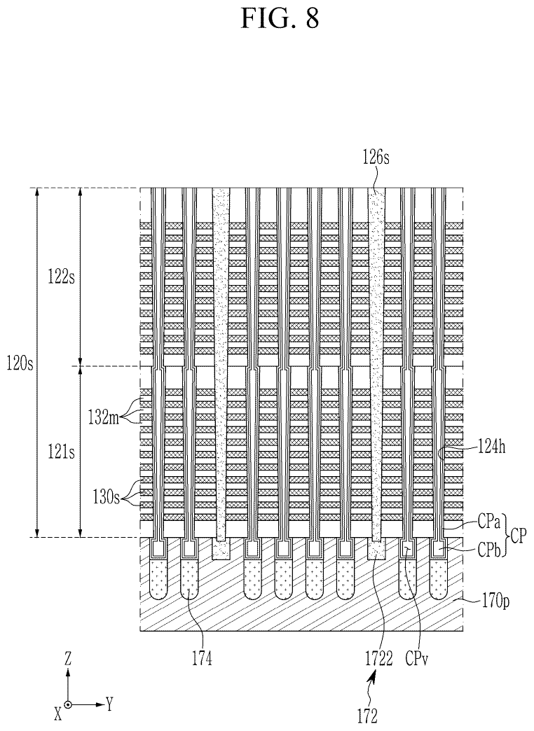

In an example embodiment, in a manufacturing method of the semiconductor device 10, a channel structure (e.g., a preliminary channel structure CP (refer to FIG. 8)) may include a penetration portion (e.g., a first penetration portion CPa (refer to FIG. 8)) and an expanded portion (e.g., a first expanded portion CPb (refer to FIG. 8)). The guide pattern 174 may be formed to correspond to the first expanded portion CPb and may have an area same as or similar to an area of the first expanded portion CPb. In a process of removing the guide pattern 174, the first expanded portion CPb may be removed together. Thereby, the through hole 170h may be formed in a portion where the guide pattern 174 and the first expanded portion CPb were disposed. The first penetration portion CPa and the first expanded portion CPb of the channel structure (e.g., the preliminary channel structure CP), and a manufacturing method of the first contact portion 164 using the guide pattern 174 will be described later in more detail in a manufacturing method of the semiconductor device 10.

In an example embodiment, the separation structure 146 may include a penetration portion (e.g., a second penetration portion 146a) and an expanded portion (e.g., a second expanded portion 146b). The second penetration portion 146a may pass through the gate stacking structure 120. The second expanded portion 146b may be connected to the second penetration portion 146a on the first surface 120a of the gate stacking structure 120 and may have a width or an area greater than a width or an area of the second penetration portion 146a. The width of the second penetration portion 146a may refer to a width (e.g., a long width or a diameter) of a portion of the second penetration portion 146a that is adjacent to the first surface 120a of the gate stacking structure 120, and the width of the second expanded portion 146b may refer to a width (e.g., a long width or a diameter) of a portion of the second expanded portion 146b that is adjacent to the first surface 120a of the gate stacking structure 120. The area of the second penetration portion 146a may refer to an area of the portion of the second penetration portion 146a that is adjacent to the first surface 120a of the gate stacking structure 120, and the area of the second expanded portion 146b may refer to an area of the portion of the second expanded portion 146b that is adjacent to the first surface 120a of the gate stacking structure 120.

A filling material for a separation structure may not entirely fill in the second expanded portion 146b and a void 146v may remain in the second expanded portion 146b. However, example embodiments are not limited thereto.

The second expanded portion 146b of the separation structure 146 may be formed together with the first expanded portion CPb of the preliminary channel structure CP, and a height H2 of the second expanded portion 146b of the separation structure 146 may be same as a height of the first expanded portion CPb of the preliminary channel structure CP.

In an example embodiment, a plurality of first contact portions 164 may be disposed to correspond to a plurality of channel structures CH, respectively. For example, in a plan view, each first contact portion 164 may overlap an entire portion of a corresponding channel structure CH.

In an example embodiment, a width or an area of the first contact portion 164 may be greater than a width or an area of the channel structure CH. The width of the first contact portion 164 may refer to a width (e.g., a long width or a diameter) of a portion of the first contact portion 164 that is adjacent to the first surface 120a of the gate stacking structure 120, and the width of the channel structure CH may refer to a width (e.g., a long width or a diameter) of a portion of the channel structure CH that is adjacent to the first surface 120a of the gate stacking structure 120. The area of the first contact portion 164 may refer to an area of the portion of the first contact portion 164 that is adjacent to the first surface 120a of the gate stacking structure 120, and the area of the channel structure CH may refer to an area of the portion of the channel structure CH that is adjacent to the first surface 120a of the gate stacking structure 120. This may be because the through hole 170h may be formed through removing the first expanded portion CPb and the guide pattern 174 having widths or areas greater than a width or an area of the first penetration portion CPa, and the liner layer 178 and the first contact portion 164 may be formed in the through hole 170h.

In an example embodiment, the width of the first contact portion 164 may be greater than a width of the first wiring 162. For example, the width of the first contact portion 164 that is directly connected to or is in direct contact with the channel structure CH and/or the first wiring 162 may be greater than the width of the first wiring 162. The width of the first contact portion 164 may refer to a width (e.g., a long width or a diameter) of a portion of the first contact portion 164 that is adjacent to the first wiring 162, and the width of the first wiring 162 may refer to a maximum line width.

In an example embodiment, a height H1 of the first contact portion 164 may be greater than the height H2 of the second expanded portion 146b of the separation structure 146. This may be because the guide pattern 174 may be further formed on a portion corresponding to the first expanded portion CPb, which corresponds to the second expanded portion 146b, the through hole 170h may be formed through removing the first expanded portion CPb and the guide pattern 174, and the liner layer 178 and the first contact portion 164 may be formed in the through hole 170h, as described above. The height H1 of the first contact portion 164 may be relatively large, and the second expanded portion 146b of the separation structure 146 may be spaced apart from the first wiring 162 while interposing the first portion 170a. Accordingly, an electrically insulation property may be improved.

A thickness T1 of the first portion 170a of the undoped semiconductor layer 170 may be greater than a thickness of the interlayer insulation layer 132m or a thickness of the gate electrode 130. The thickness T1 of the first portion 170a of the undoped semiconductor layer 170 may be greater than the height H2 of the second expanded portion 146b of the separation structure 146.

In an example embodiment, it is illustrated and described that the first contact portion 164 that passes through the undoped semiconductor layer 170 is the bit line contact and the first wiring 162 that is connected to the first contact portion 164 is the bit line BL. However, example embodiments are not limited thereto, and the first wiring 162 may be a wiring other than the bit line BL, and the first contact portion 164 may be a wiring contact that is connected to the wiring other than the bit line BL.

According to an example embodiment, the first contact portion 164 (e.g., the bit line contact) may be formed by a self-alignment process using an etching stopping pattern 172 (refer to FIG. 5) and/or the guide pattern 174. Thereby, the first contact portion 164 (e.g., the bit line contact) may be formed at a desired position without an additional mask, and undesirable defects (e.g., misalignment of the first contact portion 164 and the channel structure CH, breakage of the first expanded portion CPb, or the like) may be reduced or prevented. Thereby, reliability and/or productivity of the semiconductor device 10 may be improved.

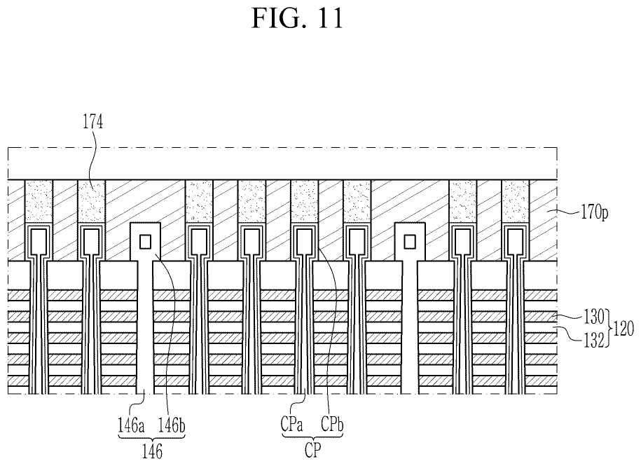

FIG. 5 to FIG. 16 are cross-sectional views that illustrate a manufacturing method of a semiconductor device according to an example embodiment. Hereinafter, a manufacturing method of a semiconductor device will be described mainly with respect to a gate stacking structure 120, a channel structure CH, a separation structure 146, a bit line BL, and a first contact portion 164 (e.g., a bit line contact) that are included in a cell region. FIG. 5 to FIG. 10 illustrate a portion corresponding to a cell array region 102 in FIG. 1, and FIG. 11 to FIG. 16 illustrate a portion corresponding to FIG. 4.

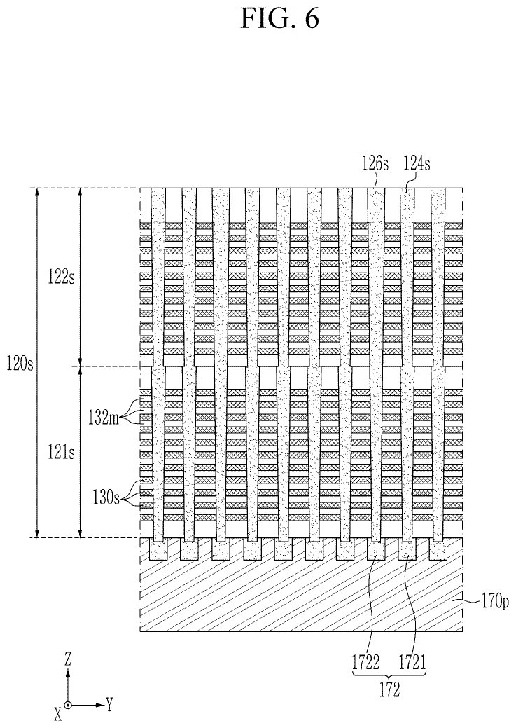

As illustrated in FIG. 5 and FIG. 6, a preliminary structure including a semiconductor substrate 170p and a stacking structure 120s may be formed. The semiconductor substrate 170p may include an etching stopping pattern 172. The stacking structure 120s may be disposed on the semiconductor substrate 170p, and include a plurality of sacrificial insulation layers 130s and a plurality of interlayer insulation layers 132m.

For example, as illustrated in FIG. 5, an etching stopping pattern 172 may be formed in the semiconductor substrate 170p.

In an example embodiment, the semiconductor substrate 170p may include or be formed of a semiconductor material. For example, the semiconductor substrate 170p may be a semiconductor substrate including or be forming of a semiconductor material, or a semiconductor substrate in which a semiconductor layer is disposed on a base substrate. For example, the semiconductor substrate 170p may include or be formed of a single-crystalline or polycrystalline silicon, germanium, silicon-germanium, or be silicon-on-insulator, germanium-on-insulator, or the like. The semiconductor substrate 170p may include or be formed of an undoped semiconductor material (e.g., a first semiconductor material) that does not include a n-type dopant or a p-type dopant.

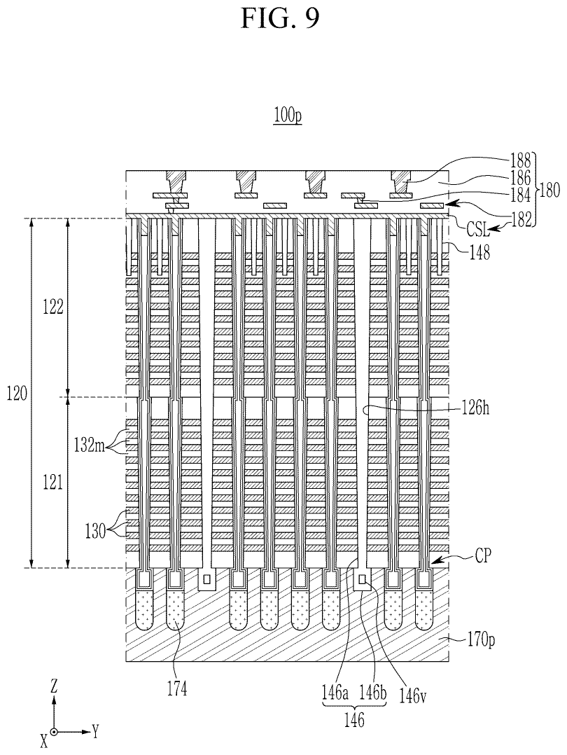

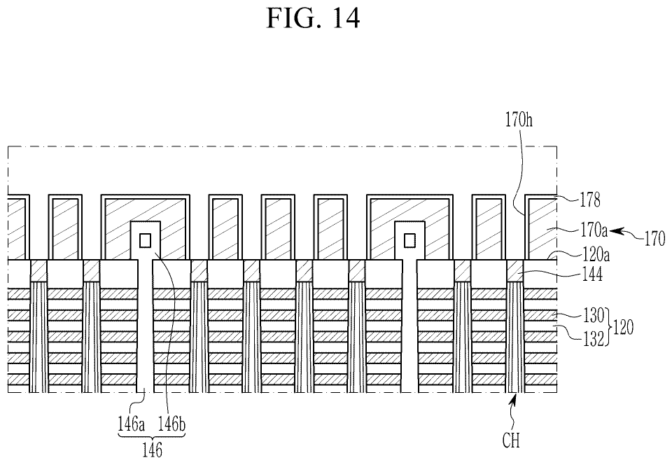

The etching stopping pattern 172 may include a first stopping pattern 1721 and a second stopping pattern 1722. In a plan view, the first stopping pattern 1721 may be disposed in a portion where a preliminary channel structure CP (refer to FIG. 8) or a channel structure CH (refer to FIG. 14) will be disposed. In a plan view, the second stopping pattern 1722 may be disposed in a portion where a separation structure 146 (refer to FIG. 9) will be disposed. The first stopping pattern 1721 may be a portion where a first expanded portion CPb (refer to FIG. 8) of the preliminary channel structure CP will be disposed, and the second stopping pattern 1722 be a portion where a second expanded portion 146b (refer to FIG. 9) of the separation structure 146 will be disposed.

The first stopping pattern 1721 may have a corresponding shape with the channel structure CH and may have a width or an area greater than a width or an area of the channel structure CH, and the second stopping pattern 1722 may have a corresponding shape with the separation structure 146 and may have a width or an area greater than a width or an area of the separation structure 146. The corresponding shape may refer to have a substantially same planar shape except for a difference in area or width.

For example, the first stopping pattern 1721 may have any of various planar shapes such as a circular shape, an oval shape, a polygonal shape, or the like, as the channel structure CH, and may have a width or an area greater than a width or an area of the channel structure CH. For example, the second stopping pattern 1722 may have a planar shape that extends in a first direction (an X-axis direction in the drawings), as the separation structure 146, and may have a width or an area greater than a width or an area of the separation structure 146.

However, example embodiments are not limited thereto, and the etching stopping pattern 172 (e.g., the first stopping pattern 1721 or the second stopping pattern 1722) may have any of various shapes, arrangements, or the like

For example, a groove 172a may be formed in a portion where the etching stopping pattern 172 will be disposed. For example, a first groove 1721a for forming the first stopping pattern 1721 and the second groove 1722a for forming the second stopping pattern 1722 may be formed. The groove 172a may be formed by any of various processes. For example, the groove 172a may be formed by an etching process using a photolithography process, but example embodiments are not limited thereto. The first stopping pattern 1721 and the second stopping pattern 1722 may be formed by filling a sacrificial material in the first groove 1721a and the second groove 1722a.

In an example embodiment, the etching stopping pattern 172 may include or be formed of at least one of a semiconductor material (e.g., polycrystalline silicon), metal (e.g., tungsten), metal nitride (e.g., tungsten nitride or titanium nitride), or carbon. The etching stopping pattern 172 may include a single layer or a plurality of layers. In some example embodiments, an interface layer that includes an insulating material and is disposed between the semiconductor substrate 170p and the etching stopping pattern 172 may be further included, but example embodiments are not limited thereto.

As illustrated in FIG. 6, by forming the stacking structure 120s, the preliminary structure may be formed. A channel sacrificial layer 124s and a separation sacrificial layer 126s may be formed to pass through the stacking structure 120s. The channel sacrificial layer 124s may be a portion that will be replaced with a channel structure CH (refer to FIG. 14) through a subsequent process. The channel sacrificial layer 124s may be formed to correspond to at least a portion of the channel structure CH. The separation sacrificial layer 126s may be a portion that will be replaced with a separation structure 146 (refer to FIG. 9) through a subsequent process. The separation sacrificial layer 126s may be formed to correspond to at least a portion of the separation structure 146.

For example, the stacking structure 120s may be formed by alternately stacking interlayer insulation layers 132m and sacrificial insulation layers 130 s on the semiconductor substrate 170p. The sacrificial insulation layer 130s may be a layer that will be replaced with a gate electrode 130 (refer to FIG. 9) through a subsequent process. The sacrificial insulation layer 130s may be formed to correspond to a portion where the gate electrode 130 will be formed.

The sacrificial insulation layer 130s may include a material different from a material of the interlayer insulation layer 132m. For example, the interlayer insulation layer 132m may include or be formed of silicon oxide, silicon nitride, silicon oxynitride, a low dielectric constant material, or the like. The sacrificial insulation layer 130s may include at least one of silicon, silicon oxide, silicon carbide, silicon nitride, or the like, and may include a material different from a material of the interlayer insulation layer 132m.

Subsequently, a first preliminary penetration part and a second preliminary penetration part may be formed, and the channel sacrificial layer 124s and the separation sacrificial layer 126s may be formed. The first preliminary penetration part may be formed to correspond to a portion where the channel structure CH will be formed. The second preliminary penetration part may be formed to correspond to a portion where the separation structure 146 will be formed. The channel sacrificial layer 124s and the separation sacrificial layer 126s may be formed by filling a sacrificial material in the first preliminary penetration part and the second preliminary penetration part, respectively.

An end of the first preliminary penetration part or the channel sacrificial layer 124s that is adjacent to the semiconductor substrate 170p may be disposed in the first stopping pattern 1721, and an end of the second preliminary penetration part or the separation sacrificial layer 126s that is adjacent to the semiconductor substrate 170p may be disposed in the second stopping pattern 1722. The first stopping pattern 1721 may have a width or an area greater than a width or an area of the channel structure CH as described above, and an entire portion of the end of the first preliminary penetration part or the channel sacrificial layer 124s may be stably disposed in the first stopping pattern 1721. The second stopping pattern 1722 may have a width or an area greater than a width or an area of the separation structure 146, and an entire portion of the end of the second preliminary penetration part or the separation sacrificial layer 126s may be stably disposed in the second stopping pattern 1722.

In an example embodiment, the first preliminary penetration part and/or the second preliminary penetration part may be formed by an etching process or the like, and a process of filling the first preliminary penetration part and/or the second preliminary penetration part may be performed by any of various processes (e.g., a deposition process or the like). The channel sacrificial layer 124s and/or the separation sacrificial layer 126s may include or be formed of at least one of a semiconductor material (e.g., polycrystalline silicon), metal (e.g., tungsten), metal nitride (e.g., tungsten nitride or titanium nitride), or carbon. For example, the channel sacrificial layer 124s and/or the separation sacrificial layer 126s may include a material same as or different from a material of the first stopping pattern 1721 and/or the second stopping pattern 1722.

In an example embodiment, the first preliminary penetration part and the second preliminary penetration part may be formed together, and the process of filling the first preliminary penetration part and the process of filling the second preliminary penetration part may be performed together. However, example embodiments are not limited thereto. An order of a process of forming the first preliminary penetration part, a process of forming the second preliminary penetration part, a process of filling the first preliminary penetration part, and a process of filling the second preliminary penetration part may be variously modified.

In an example embodiment, the stacking structure 120s may include a plurality of stacking structures 121s and 122s sequentially stacked on the semiconductor substrate 170p, and the channel sacrificial layer 124s may include a plurality of portions that pass through the plurality of stacking structures 121s and 122s, respectively. The separation sacrificial layer 126s may include a single portion that passes through the plurality of stacking structures 121s and 122s. However, example embodiments are not limited thereto.

Subsequently, as illustrated in FIG. 7, a first penetration part 124h may be formed by removing the channel sacrificial layer 124s (refer to FIG. 6) and the first stopping pattern 1721 (refer to FIG. 6). A guide pattern 174 may be formed by forming a guide groove 174a under a portion corresponding to the first stopping pattern 1721 through the first penetration part 124h and forming a guide material in the guide groove 174a.

The process of forming the first penetration part 124h may be performed by any of various processes (e.g., an etching process or the like). The first penetration part 124h may include a penetration portion 1241h that corresponds to a portion in which the channel sacrificial layer 124s was disposed and has been removed and a groove portion 1242h that corresponds to a portion in which the first stopping pattern 1721 was disposed and has been removed. The penetration portion 1241h may pass the stacking structure 120s, and the groove portion 1242h may be disposed on a first surface of the stacking structure 120s and may have a width or an area greater than a width or an area of the penetration portion 1241h.

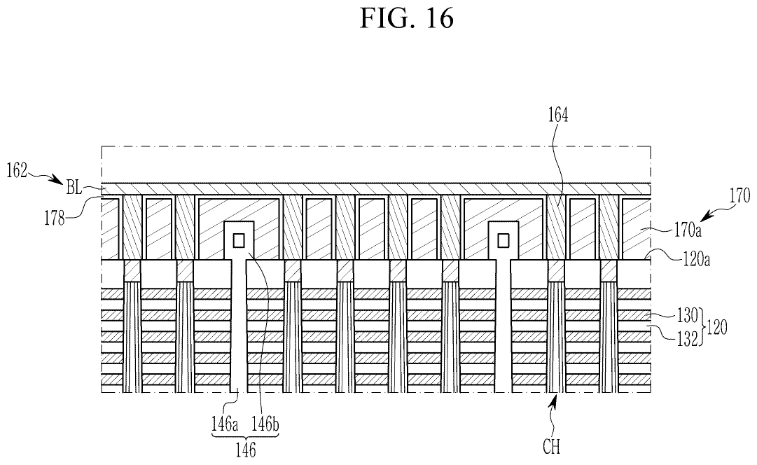

The guide pattern 174 may be disposed to correspond to at least a portion of a region where a first contact portion 164 configured to connect the channel structure CH to the first wiring portion 160 will be disposed. For example, the guide pattern 174 may be disposed to correspond to at least a portion of a region where the first contact portion 164 (e.g., the bit line contact) configured to connect the channel structure CH to a bit line BL (refer to FIG. 16) will be disposed. The guide pattern 174 may be referred to as a place holder, a position indication pattern, a self-alignment pattern, a preliminary pattern for a contact portion, or the like.

The guide pattern 174 may include a guide material that is different from a material of the semiconductor substrate 170p or has a composition different from a composition of the semiconductor substrate 170p. In an example embodiment, the guide material included in the guide pattern 174 may include a semiconductor material that is different from a material of the semiconductor substrate 170p or has a composition different from the composition of the semiconductor substrate 170p. That is, the semiconductor substrate 170p may include a first semiconductor material, and the guide pattern 174 may include a second semiconductor material that is different from the first semiconductor material or has a composition different from a composition of the first semiconductor material. For example, the semiconductor substrate 170p may include or be formed of silicon (e.g., undoped silicon), and the guide pattern 174 may include or be formed of silicon-germanium (e.g., undoped silicon-germanium), germanium (e.g., undoped germanium), or the like. However, example embodiments are not limited thereto, and the semiconductor substrate 170p and/or the guide pattern 174 may include any of various materials.

The guide groove 174a may be formed by any of various processes. For example, the guide groove 174a may be formed by an etching process, but example embodiments are not limited thereto. The process of forming the guide material in the guide groove 174a may be performed by any of various processes (e.g., an epitaxial process or the like). In some example embodiments, after forming the guide pattern 174 in the guide groove 174a, a process of etching a portion of the guide pattern 174 may be performed to adjust a height or a shape of the guide pattern 174.

In an example embodiment, the guide groove 174a or the guide pattern 174 may include a portion having a width or an area same as a width or an area of the groove portion 1242h of the first penetration part 124h. This may be because, in a manufacturing process of a semiconductor device, the guide groove 174a is formed by an etching process performed through the groove portion 1242h to have an area same as or substantially similar to an area of the groove portion 1242h. For example, a lower surface of the groove portion 1242h and an upper surface of the guide groove 174a that are adjacent to (e.g., in contact with) each other may have a same area. When the guide groove 174a may be etched more in the etching process of forming the guide groove 174a, the first contact portion 164 may include a portion having a width or an area greater than a width or an area of a first expanded portion CHb (refer to FIG. 8) of the preliminary channel structure CP.

A side surface of the guide groove 174a or the guide pattern 174 may be disposed on a same plane as a side surface of the first penetration part 124h (e.g., the groove portion 1242h). For example, the side surface of the guide groove 174a or the guide pattern 174 may include a vertical surface or an inclined surface that is disposed on a same plane as the side surface of the first penetration part 124h. This may be because the guide groove 174a may be formed through the first penetration part 124h. However, example embodiments are not limited thereto, and the side surface of the guide groove 174a or the guide pattern 174 may have any of various shapes.

In the drawings, it is illustrated as an example that the lower surface of the guide groove 174a or the guide pattern 174 has a rounded shape. However, example embodiments are not limited thereto. The lower surface of the guide groove 174a or the guide pattern 174 may be a flat surface, or a shape of the lower surface of the guide groove 174a or the guide pattern 174 may be variously modified.

In an example embodiment, in a thickness direction of a semiconductor device or a vertical direction (a Z-axis direction in the drawings), a height of the guide pattern 174 may be greater than a height of the etching stopping pattern 172. Thereby, the first contact portion 164 may be stably formed. However, example embodiments are not limited thereto, and the height of the guide pattern 174 may be same as or less than the height of the etching stopping pattern 172.

Subsequently, as illustrated in FIG. 8, at least a portion of the channel structure CH (e.g., the preliminary channel structure CP) may be formed in the first penetration part 124h. The preliminary channel structure CP may be a structure where a channel pad or the like is not formed. For a clear understanding, the term of the preliminary channel structure CP may be used to discriminate a structure where the channel pad or the like is not formed from the channel structure CH where the channel pad or the like is formed. The preliminary channel structure CP may be referred to as the channel structure CH because the preliminary channel structure CP is a structure for forming the channel structure CH in a manufacturing process.

For example, a gate dielectric layer 150 (refer to FIG. 2), a channel layer 140 (refer to FIG. 2), and a core insulation layer 142 (refer to FIG. 2) may be sequentially in the first penetration part 124h. In this instance, a first blocking layer 156a (refer to FIG. 2) of the gate dielectric layer 150 may not be formed, and may be formed in a subsequent process. The process of forming the gate dielectric layer 150, the channel layer 140, or the core insulation layer 142 may be performed by any of various processes (e.g., a deposition process or the like). In a plan view, the preliminary channel structure CP may be formed to correspond to the guide pattern 174.

In an example embodiment, the preliminary channel structure CP may include a penetration portion (e.g., a first penetration portion CPa) and an expanded portion (e.g., a first expanded portion CPb). The first penetration portion CPa may through the stacking structure 120s, and the first expanded portion CPb may be connected to the first penetration portion CPa on the first surface of the stacking structure 120s and may have a width or an area greater than a width or an area of the first penetration portion CPa. The width of the first penetration portion CPa may refer to a width (e.g., a long width or a diameter) of a portion of the first penetration portion CPa that is adjacent to the first surface of the stacking structure 120s, and the width of the first expanded portion CPb may refer to a width (e.g., a long width or a diameter) of a portion of the first expanded portion CPb that is adjacent to the first surface of the stacking structure 120s. The area of the first penetration portion CPa may refer to an area of the portion of the first penetration portion CPa that is adjacent to the first surface of the stacking structure 120s, and the area of the first expanded portion CPb may refer to an area of the portion of the first expanded portion CPb that is adjacent to the first surface of the stacking structure 120s.

A filling material for a channel structure may not entirely fill in the first expanded portion CPb and a void CPv may remain in the first expanded portion CPb. However, example embodiments are not limited thereto.

Subsequently, as illustrated in FIG. 9, the separation sacrificial layer 126s (refer to FIG. 8) and the second stopping pattern 1722 (refer to FIG. 8) may be removed to form a second penetration part 126h, the sacrificial insulation layer 130s (refer to FIG. 8) may be replaced with a gate electrode 130, and an insulating material may be filled in at least a portion of the second penetration part 126h to form a separation structure 146. A separation pattern 148 may be formed, and a second wiring portion 180 may be formed.

The process of forming the second penetration part 126h may be performed by any of various processes (e.g., an etching process or the like).

By an etching process (e.g., a wet etching process) through the second penetration part 126h, the sacrificial insulation layer 130s may be selectively removed. The gate electrode 130 may be formed by filling a conductive material in a portion where the sacrificial insulation layer 130s has been removed. The process of forming the gate electrode 130 may be performed by any of various processes (e.g., a deposition process or the like). Thereby, a horizontal region where the sacrificial insulation layer 130s has been disposed may be replaced with the gate electrode 130. Before the process of filling the conductive material of the gate electrode 130, a process of forming a first blocking layer 156a (refer to FIG. 2) may be further performed.

Thereby, a gate stacking structure 120 including the gate electrode 130 and the interlayer insulation layer 132m may be formed. In an example embodiment, the gate stacking structure 120 may include a plurality of gate stacking portions 121 and 122 that are sequentially stacked on the semiconductor substrate 170p. However, example embodiments are not limited thereto.

The process of filling the second penetration part 126h may be performed by any of various processes (e.g., a deposition process or the like). For example, an insulation layer may fill the second penetration part 126h. For example, the insulation layer may include a single layer or a plurality of layers.

In an example embodiment, the separation structure 146 may include a penetration portion (e.g., a second penetration portion 146a) and an expanded portion (e.g., a second expanded portion 146b).

In an example embodiment, the separation pattern 148 may be formed in a portion of the stacking structure 120s (refer to FIG. 8) or the gate stacking structure 120. The separation pattern 148 may be formed by forming an opening for the separation pattern through an etching process using a mask layer and filling an insulating material in at least a portion of the opening for the separation pattern. An order of a process of forming the separation pattern 148 may be variously changed in a manufacturing method of a semiconductor device.

The second wiring portion 180 that includes a second wiring 182 including a common source electrode CSL, a second contact portion 184, a second insulation layer 186, and a bonding structure 188 may be formed. Thereby, a preliminary cell region 100p may be manufactured.

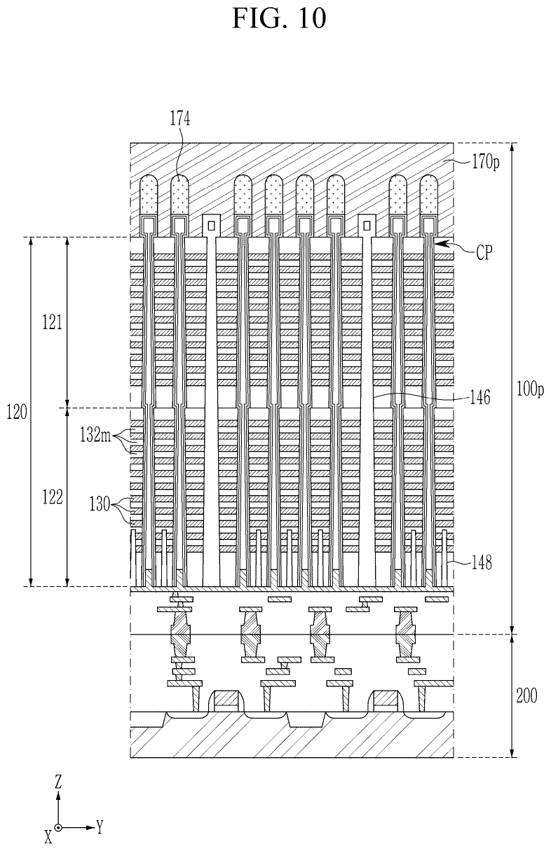

Subsequently, as illustrated in FIG. 10, the preliminary cell region 100p may be bonded to a circuit region 200. For example, on the circuit region 200, the preliminary cell region 100p may be bonded to have a reversed structure in the thickness direction of the vertical direction (the Z-axis in the drawings). In the reversed structure, a portion of the preliminary cell region 100p far away from the semiconductor substrate 170p may be disposed to face the circuit region 200. Hybrid junction may be performed through an annealing process in a state that the circuit region 200 and the preliminary cell region 100p are in contact with each other.

Subsequently, as illustrated in FIG. 11, a thinning process may be performed. In the thinning process, portions of the semiconductor substrate 170p and the guide pattern 174 may be removed to expose the guide pattern 174 to an outside in the thickness direction or the vertical direction (the Z-axis direction in the drawings). Thereby, a first surface (an upper surface in FIG. 11) of the guide pattern 174 may be exposed to an outside.

The thinning process may be performed by using at least one of a grinding process or a chemical mechanical polishing process. However, example embodiments are not limited thereto, and the thinning process may be performed by any of various processes.

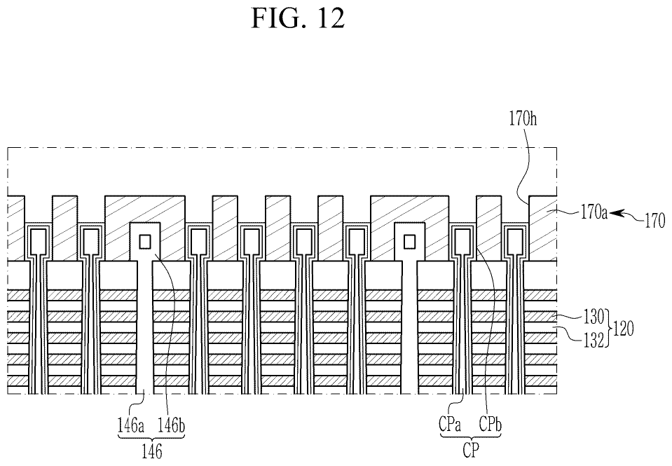

Subsequently, as illustrated in FIG. 12 to FIG. 16, a first wiring portion 160 may be formed. The first wiring portion 160 may include a first contact portion 164 in a through hole 170h where the guide pattern 174 (refer to FIG. 11) has been removed and a first wiring 162 that is electrically connected to the first contact portion 164.

For example, as illustrated in FIG. 12, the guide pattern 174 may be selectively removed. For example, the guide pattern 174 may be selectively removed through an etching process (e.g., a dry etching process). For example, in the etching process, an etching material capable of etching the guide pattern 174 more than the semiconductor substrate 170p or etching the guide pattern 174 without etching the semiconductor substrate 170p may be used. Thereby, the through hole 170h where the guide pattern 174 is removed may be formed.

In some example embodiments, after the guide pattern 174 is removed, a process of additionally removing a portion of the semiconductor substrate 170p in the thickness direction or the vertical direction (the Z-axis direction in the drawings) may be performed. Thereby, a height of the through hole 170h may be adjusted. The process of additionally removing the portion of the semiconductor substrate 170p may be performed by an etching process. However, example embodiments are not limited thereto, and the process of additionally removing the portion of the semiconductor substrate 170p may be performed by any of various processes. In some example embodiments, the process of additionally removing the portion of the semiconductor substrate 170p may be omitted.

Thereby, the undoped semiconductor layer 170 (e.g., a first portion 170a) having the through hole 170h may be formed.

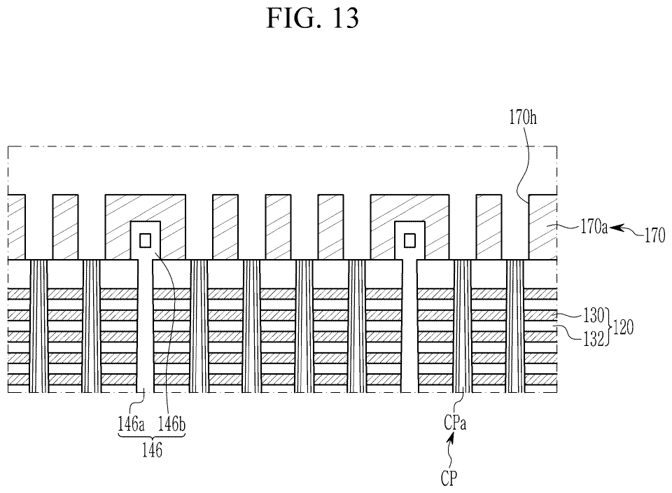

Subsequently, as illustrated in FIG. 13, the first expanded portion CPb (refer to FIG. 12) of the preliminary channel structure CP may be removed. The process of removing the first expanded portion CPb of the preliminary channel structure CP may be performed by any of various processes (e.g., an etching process or the like).

Subsequently, as illustrated in FIG. 14, a liner layer 178 may be formed on an inner side surface and/or an upper surface of the undoped semiconductor layer 170 (e.g., the first portion 170a), and a channel pad 144 (e.g., a first channel pad) of a channel structure CH may be formed. For example, the channel pad 144 may be formed by removing a portion of the liner layer 178 and a portion of the preliminary channel structure CP (refer to FIG. 13) that are adjacent to a first surface 120a of the gate stacking structure 120 and filling a conductive material (e.g., a doped semiconductor material) in a portion where the portion of the preliminary channel structure CP is removed.

The process of forming the liner layer 178 may be performed by any of various processes (e.g., a deposition process or the like). The process of removing the portion of the liner layer 178 and/or the portion of the preliminary channel structure CP may be performed by any of various processes (e.g., an etching process or the like), and the process of forming the channel pad 144 may be performed by any of various processes (e.g., a deposition process or the like).

In an example embodiment, it is described as an example that the liner layer 178 includes a portion on the inner side surface and the upper surface of the undoped semiconductor layer 170 (e.g., the first portion 170a). Thereby, a manufacturing process may be simplified. However, example embodiments are not limited thereto. In some example embodiments, a portion on the inner side surface of the undoped semiconductor layer 170 (e.g., the first portion 170a) and a portion on the upper surface of the undoped semiconductor layer 170 (e.g., the first portion 170a) may be formed by separate processes.

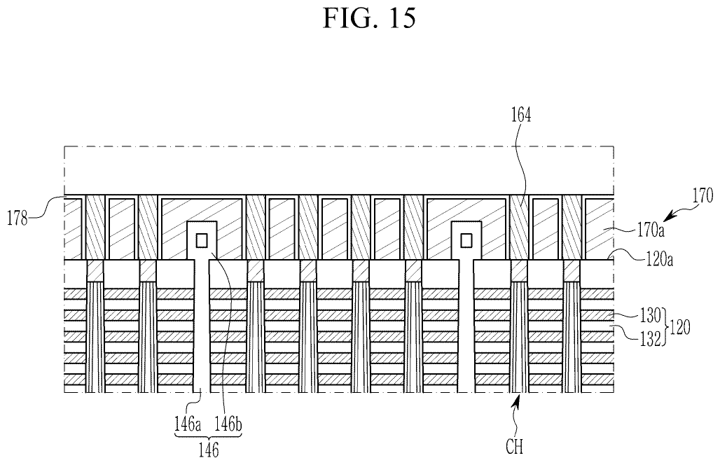

Subsequently, as illustrated in FIG. 15, a first contact portion 164 may be formed on the liner layer 178 in the through hole 170h. The first contact portion 164 may be electrically connected to (e.g., be directly connected to or be in direct contact with) the channel structure CH (e.g., the channel pad 144). The process of forming the first contact portion 164 may be performed by any of various processes (e.g., a deposition process or the like).

In an example embodiment, the first contact portion 164 may be formed in the portion where the first stopping pattern 1721 (refer to FIG. 6) and the guide pattern 174 (refer to FIG. 10) under a portion corresponding to the first stopping pattern 1721 are removed. Accordingly, the first contact portion 164 may be formed by a self-alignment.

Subsequently, as illustrated in FIG. 16, a bit line BL that is electrically connected to the first contact portion 164 may be formed on a surface of the undoped semiconductor layer 170. The process of forming the bit line BL may be performed by any of various processes (e.g., a deposition process or the like). Thereby, a first wiring portion may be formed. Subsequently, an outer insulation layer, an input/output contact portion, an input/output pad, or the like may be further formed.

According to an example embodiment, the first contact portion 164 (e.g., the bit line contact) may be formed by a self-alignment process using the etching stopping pattern 172 and/or the guide pattern 174. Accordingly, the first contact portion 164 (e.g., the bit line contact) that electrically connects the channel structure CH and the first wiring 162 (e.g., the bit line BL) may be stably formed at a desired position by a relatively easy process. Thereby, reliability and/or productivity of a semiconductor device may be improved.

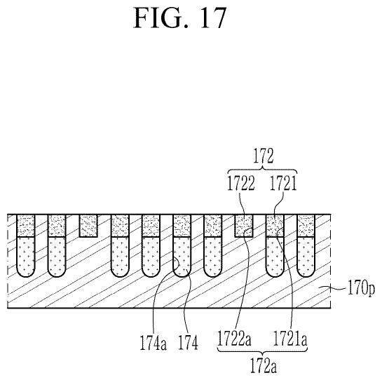

Hereinafter, referring to FIG. 17 to FIG. 20, semiconductor devices according to modified example embodiments and manufacturing methods of the same will be described in detail. To the extent that an element is not described in detail below, it may be understood that the element is at least similar to a corresponding element that has been described elsewhere within the present disclosure. A portion which is not described in the above will be described in detail.

FIG. 17 is a cross-sectional view that illustrates a part of a manufacturing method of a semiconductor device according to a modified example embodiment.

Referring to FIG. 17, in a modified example embodiment, an etching stopping pattern 172 and a guide pattern 174 may be formed in a semiconductor substrate 170p before forming a stacking structure 120s (refer to FIG. 6). The etching stopping pattern 172 may include a first stopping pattern 1721 and a second stopping pattern 1722. The first stopping pattern 1721 may be disposed in a portion where a channel structure will be formed in a plan view. The second stopping pattern 1722 may be disposed in a portion where a separation structure will be formed in a plan view. The guide pattern 174 may be disposed under the first stopping pattern 1721.

For example, a groove 172a may be formed to correspond to a portion where the etching stopping pattern 172 will be disposed. For example, a first groove 1721a for forming the first stopping pattern 1721 and a second groove 1722a for forming the second stopping pattern 1722 may be formed. The groove 172a may be formed by any of various processes. For example, the groove 172a may be formed by an etching process using a photolithography process, but example embodiments are not limited thereto.

The guide pattern 174 may be formed by forming a guide groove 174a under the first groove 1721a (e.g., under a portion corresponding to the first stopping pattern 1721) through the first groove 1721a and forming a guide material in the guide groove 174a. In the process of forming the guide groove 174a, a mask may be formed in a portion other than the first groove 1721a and the guide groove 174a may not be formed in a portion corresponding to the second groove 1722a. Any of various processes may be used for the process of forming the guide groove 174a in the portion corresponding to the first groove 1721a and not forming the guide groove 174a in the portion corresponding to the second groove 1722a.

Subsequently, a preliminary cell region may be formed. For example, a stacking structure, a channel sacrificial layer, and a separation sacrificial layer may be formed as illustrated in FIG. 6, a preliminary channel structure may be formed as illustrated in FIG. 7 and FIG. 8, and a sacrificial insulation layer may be replaced with a gate electrode and a separation structure, a separation pattern, a second wiring portion, or the like may be formed as illustrated in FIG. 9. A semiconductor device may be manufactured by performing processes described with reference to FIG. 10 to FIG. 16.

According to an example embodiment, by forming the guide pattern 174 before forming the stacking structure, the process of forming the guide pattern 174 may be easily performed.

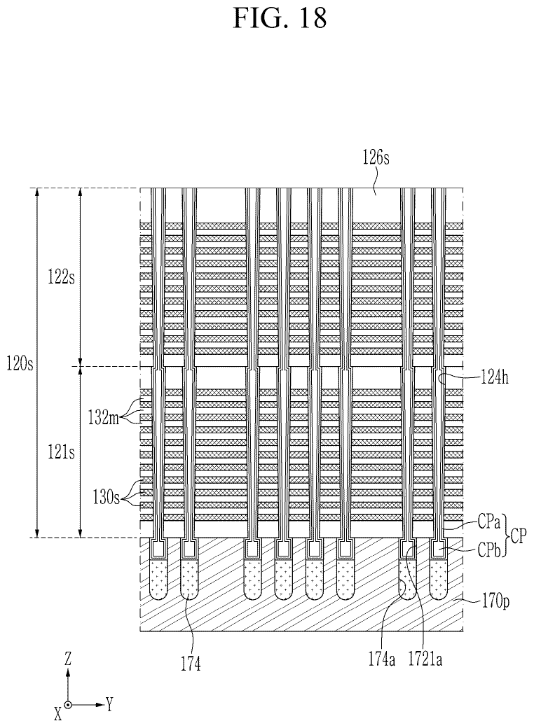

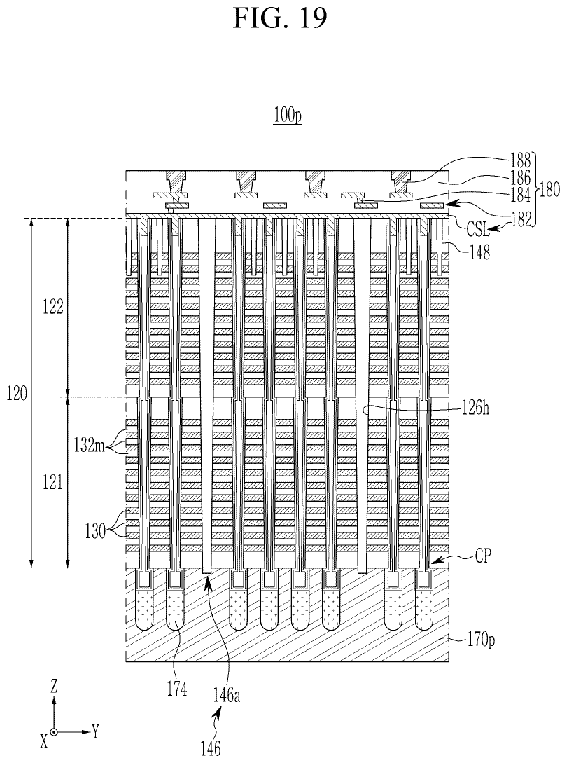

FIG. 18 and FIG. 19 are cross-sectional views that illustrate a part of a manufacturing method of a semiconductor device according to a modified example embodiment.

Referring to FIG. 18, in a modified example embodiment, an etching stopping pattern 172 and a guide pattern 174 may not be formed in a semiconductor substrate 170p before forming a stacking structure 120s.

The stacking structure 120s may be formed on the semiconductor substrate 170p not including the etching stopping pattern 172 and the guide pattern 174, a first preliminary penetration part passing through the stacking structure 120s may be formed, a first groove 1721a and a guide groove 174a may be formed through the first preliminary penetration part, a guide pattern 174 may be formed in the guide groove 174a, and a channel structure CH may be formed in the first penetration part 124h including the first preliminary penetration part and the first groove 1721a. In the processes of forming the first penetration part 124h, the guide pattern 174, and the channel structure CH, a separation structure, and/or a second preliminary penetration part, a second groove, or the like for the separation structure may not be formed.

Subsequently, as illustrated in FIG. 19, a second penetration part 126h may be formed, the sacrificial insulation layer 130s (refer to FIG. 18) may be replaced with a gate electrode 130, and an insulating material may be filled in at least a portion of the second penetration part 126h to form a separation structure 146. A separation pattern 148 may be formed, and a second wiring portion 180 may be formed.

In FIG. 19, it is illustrated as an example that the second penetration part 126h is formed of the second preliminary penetration part that passes through the stacking structure. Thereby, in a semiconductor device, the separation structure 146 may include a second penetration portion 146a and may not include a portion corresponding to a second expanded portion. Accordingly, a structure and a manufacturing process of the separation structure 146 may be simplified. However, example embodiments are not limited thereto, and a shape, a manufacturing process, or the like of the separation structure 146 may be variously modified.

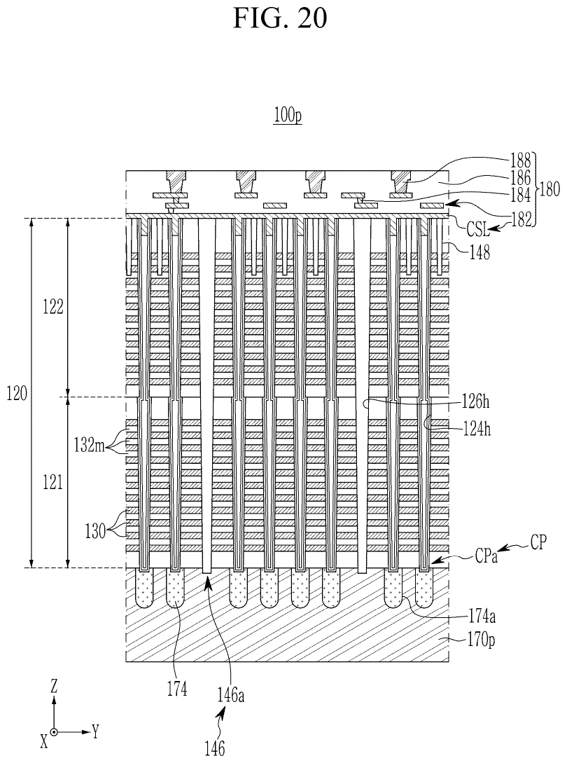

FIG. 20 is a cross-sectional view that illustrates a part of a manufacturing method of a semiconductor device according to a modified example embodiment.

Referring to FIG. 20, in a modified example embodiment, a guide pattern 174 may be formed in a semiconductor substrate 170p in a preliminary cell region 100p without an etching stopping pattern 172 (refer to FIG. 5). The guide pattern 174 may act as an etching stopping pattern. After the preliminary cell region 100p may be bonded to a circuit region, a through hole may be formed through removing the guide pattern 174, a channel pad of a channel structure may be formed through the through hole, a liner layer may be formed, and a first wiring portion including a first contact portion may be formed.

The guide pattern 174 or the guide groove 174a may be formed before a stacking structure 120s (refer to FIG. 6) is formed, or may be formed through a first penetration part 124h after the stacking structure 120s is formed.

In FIG. 20, it is illustrated as an example that the first penetration part 124h is a first preliminary penetration part that passes through the stacking structure 120s. In this instance, a preliminary channel structure CP may include a first penetration portion CPa and may not include a portion corresponding to a first expanded portion, and a channel structure may include the first penetration portion CPa and may not include the first expanded portion. Accordingly, a structure and a manufacturing process of the preliminary channel structure CP or the channel structure may be simplified. However, example embodiments are not limited thereto, and a shape, a manufacturing process, or the like of the preliminary channel structure CP or the channel structure may be variously modified.

In FIG. 20, it is illustrated as an example that the second penetration part 126h is a second preliminary penetration part that passes through the stacking structure 120s. In this instance, in a semiconductor device, a separation structure 146 may include a second penetration portion 146a and may not include a portion corresponding to a second expanded portion. Accordingly, a structure and a manufacturing process of the separation structure 146 may be simplified. However, example embodiments are not limited thereto, and a shape, a manufacturing process, or the like of the separation structure 146 may be variously modified.

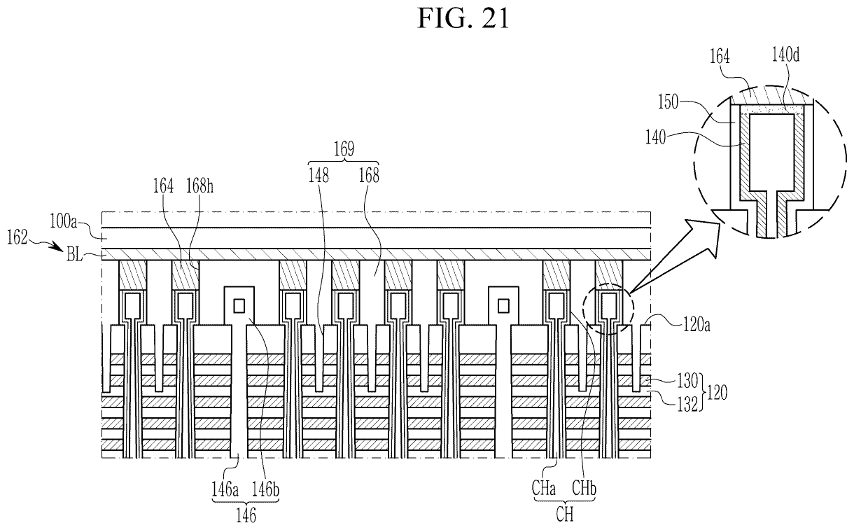

Modified example embodiments described with reference to FIG. 17 to FIG. 20 may be applied to the example embodiments described with reference to FIG. 21 to FIG. 38.

Hereinafter, referring to FIG. 21 to FIG. 38, semiconductor devices according to some example embodiments and manufacturing methods of the same will be described in detail. To the extent that an element is not described in detail below, it may be understood that the element is at least similar to a corresponding element that has been described elsewhere within the present disclosure. A portion which is not described in the above will be described in detail.

FIG. 21 is a partial cross-sectional view that illustrates a semiconductor device according to an example embodiment. FIG. 21 illustrates a portion corresponding to FIG. 4.

Referring to FIG. 21, in a semiconductor device according to an example embodiment, a channel structure CH may include a penetration portion (e.g., a first penetration portion CHa) and an expanded portion (e.g., a first expanded portion CHb). The first penetration portion CHa may pass through a gate stacking structure 120. The first expanded portion CHb may be connected to the first penetration portion CHa on a first surface 120a of the gate stacking structure 120 and may have a width or an area greater than a width or an area of the first penetration portion CHa. The width of the first penetration portion CHa may refer to a width (e.g., a long width or a diameter) of a portion of the first penetration portion CHa that is adjacent to the first surface 120a of the gate stacking structure 120, and the width of the first expanded portion CHb may refer to a width (e.g., a long width or a diameter) of a portion of the first expanded portion CHb that is adjacent to the first surface 120a of the gate stacking structure 120. The area of the first penetration portion CHa may refer to an area of the portion of the first penetration portion CHa that is adjacent to the first surface 120a of the gate stacking structure 120, and the area of the first expanded portion CHb may refer to an area of the portion of the first expanded portion CHb that is adjacent to the first surface 120a of the gate stacking structure 120.

In an example embodiment, a portion of the gate dielectric layer 150 in the first expanded portion CHb may be removed, and a portion of a channel layer 140 in an upper portion of the first expanded portion CHb may include a doping region 140d. For example, the doping region 140d of the channel layer 140 may be doped with an n-type and be an n-type region. A first contact portion 164 may be electrically connected to the doping region 140d of the channel layer 140. For example, the first contact portion 164 may be in contact with the doping region 140d of the channel layer 140. By the doping region 140d of the channel layer 140, an electrical connection property with the first contact portion 164 may be improved.

An intermediate insulation layer 168 may be disposed between the first surface 120a of the gate stacking structure 120 and the first wiring 162 (e.g., at least between the first surface 120a of the gate stacking structure 120 and a bit line BL).

The intermediate insulation layer 168 may have a layered shape disposed between the first surface 120a of the gate stacking structure 120 and the first wiring 162 (e.g., at least between the first surface 120a of the gate stacking structure 120 and the bit line BL). Having a layered shape may refer to have a shape that extends horizontally in a portion other than the first expanded portion CHb of the channel structure CH and the first contact portion 164 or in a portion other than a through hole 168h in a plan view. For example, the intermediate insulation layer 168 may have a layered shape to be connected in a portion other than a plurality of through holes 168h where a first expanded portions CHb of a plurality of channel structures CH and a plurality of first contact portions 164 connected thereto are disposed to have an integral structure. Accordingly, the plurality of through holes 168h may be disposed inside the intermediate insulation layer 168.

In an example embodiment, a separation pattern 148 may be adjacent to the first surface 120a of the gate stacking structure 120. The intermediate insulation layer 168 and the separation pattern 148 may be formed together by a same process to form a single insulation layer 169. That is, the intermediate insulation layer 168 and the separation pattern 148 may have an integral structure that include a same material and in which the intermediate insulation layer 168 and the separation pattern 148 are connected to each other.

For example, the intermediate insulation layer 168 and the separation pattern 148, or the single insulation layer 169 may include or be formed of silicon oxide, silicon nitride, silicon oxynitride, a low dielectric constant material, or the like. However, example embodiments are not limited thereto, and the intermediate insulation layer 168 and the separation pattern 148, or the single insulation layer 169 may include any of various the insulating materials.

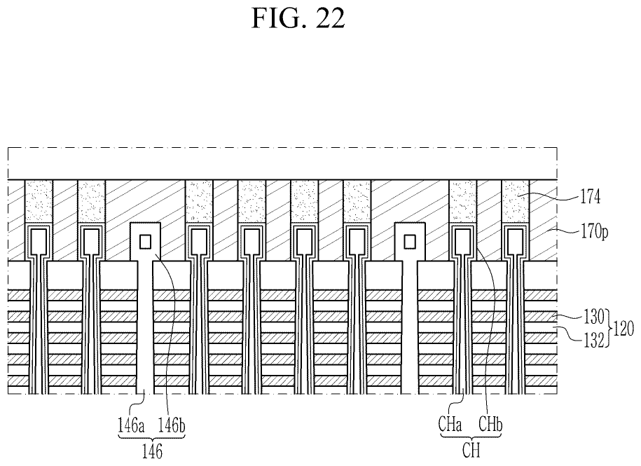

In an example embodiment, a first contact portion 164 may be formed by a self-alignment process using a semiconductor substrate 170p (refer to FIG. 22), and the semiconductor substrate 170p may be removed and be replaced with the intermediate insulation layer 168. For example, in a manufacturing method of a semiconductor device, a guide pattern 174 (refer to FIG. 22) may be formed in a portion of the semiconductor substrate 170p corresponding to at least a portion of the first contact portion 164, the semiconductor substrate 170p other than the guide pattern 174 may be removed and be replaced with the intermediate insulation layer 168, the through hole 168h may be formed through removing the guide pattern 174, the doping region 140d of the channel layer 140 may be formed in the through hole 168h, and the first contact portion 164 may be formed. Accordingly, the first contact portion 164 may be formed in a portion where the guide pattern 174 was disposed and has been moved by a self-alignment. The intermediate insulation layer 168 may be formed by replacing a portion of the semiconductor substrate 170p other than the guide pattern 174.

In an example embodiment, a separation structure 146 may include a penetration portion (e.g., a second penetration portion 146a) and an expanded portion (e.g., a second expanded portion 146b). The second penetration portion 146a may pass through the gate stacking structure 120. The second expanded portion 146b may be connected to the second penetration portion 146a on the first surface 120a of the gate stacking structure 120 and may have a width or an area greater than a width or an area of the second penetration portion 146a. However, example embodiments are not limited thereto, and the separation structure 146 may not include the second expanded portion 146b.

The second expanded portion 146b of the separation structure 146 and the first expanded portion CHb of the channel structure CH may be formed together. After the second expanded portion 146b of the separation structure 146 may be formed to have a height same as a height of the first expanded portion CHb of the channel structure CH, a portion of the gate dielectric layer 150 in the first expanded portion CHb of the channel structure CH may be removed. Accordingly, the height of the second expanded portion 146b of the separation structure 146 may have a height same as or similar to the first expanded portion CHb of the channel structure CH.

In an example embodiment, a plurality of first contact portions 164 may be disposed to correspond to the plurality of channel structures CH, respectively. The first contact portions 164 may be disposed to correspond to the channel structures CH, respectively. For example, in a plan view, each first contact portion 164 may be disposed to overlap an entire portion of the first penetration portion CHa of a corresponding channel structure CH.

In an example embodiment, a width or an area of the first contact portion 164 may be greater than a width or an area of the channel structure CH of the first penetration portion CHa. The width of the first contact portion 164 may refer to a width (e.g., a long width or a diameter) of a portion of the first contact portion 164 that is adjacent to the first surface 120a of the gate stacking structure 120, and the width of the first penetration portion CHa of the channel structure CH may refer to a width (e.g., a long width or a diameter) of a portion of the first penetration portion CHa of the channel structure CH that is adjacent to the first surface 120a of the gate stacking structure 120. The area of the first contact portion 164 may refer to an area of the portion of the first contact portion 164 that is adjacent to the first surface 120a of the gate stacking structure 120, and the area of the first penetration portion CHa of the channel structure CH may refer to an area of the portion of the first penetration portion CHa of the channel structure CH that is adjacent to the first surface 120a of the gate stacking structure 120. This may be because the through hole 168h is formed through removing the guide pattern 174 having a width or an area greater than a width or an area of the first penetration portion CPa and the first contact portion 164 is formed in the through hole 168h.

In an example embodiment, the first contact portion 164 may include a portion having a width or an area substantially same as a width or an area of the first expanded portion CHb of the channel structure CH. This may be because the guide pattern 174 for the first contact portion 164 is formed to have an area same as or substantially similar to an area of a first stopping pattern for the first expanded portion CHb in a manufacturing process of a semiconductor device. For example, an upper surface of the first expanded portion CHb and a lower surface of the first contact portion 164 that are adjacent to (e.g., in contact with) each other may have a same area. When a guide groove may be etched more in an etching process of forming the guide groove for the guide pattern 174, the first contact portion 164 may include a portion having a width or an area greater than a width or an area of the first expanded portion CHb of the channel structure CH.

A side surface of the first expanded portion CHb and a side surface of the first contact portion 164 may be disposed on a same plane. The side surface of the first expanded portion CHb and the side surface of the first contact portion 164 may include vertical surfaces or inclined surfaces that are disposed on a same plane. However, example embodiments are not limited thereto, and the side surface of the first expanded portion CHb or the side surface of the first contact portion 164 may have any of various shapes.

In an example embodiment, a width of the first contact portion 164 may be greater than a width of the first wiring 162. For example, the width of the first contact portion 164 that is directly connected to or is in direct contact with the channel structure CH and/or the first wiring 162 may be greater than the width of the first wiring 162. The width of the first contact portion 164 may refer to a width (e.g., a long width or a diameter) of a portion of the first contact portion 164 that is adjacent to the first wiring 162, and the width of the first wiring 162 may refer to a maximum line width.

In an example embodiment, the separation structure 146 may be spaced apart from the first wiring 162 while interposing the intermediate insulation layer 168. For example, the separation structure 146 may be spaced apart from the first wiring 162 by at least a height of the first contact portion 164. Accordingly, an electrically insulation property may be improved.

A thickness of the intermediate insulation layer 168 may be greater than a thickness of an interlayer insulation layer 132m or a thickness of a gate electrode 130. The thickness of the intermediate insulation layer 168 may be greater than a height of the second expanded portion 146b of the separation structure 146.

In an example embodiment, it is described as an example that the first contact portion 164 passing through the intermediate insulation layer 168 is a bit line contact and the first wiring 162 connected to the first contact portion 164 is a bit line BL. However, example embodiments are not limited thereto, and the first wiring 162 may be a wiring other than the bit line BL, and the first contact portion 164 may be a wiring contact connected to the wiring other than the bit line BL.

FIG. 22 to FIG. 28 are cross-sectional views that illustrate a manufacturing method of a semiconductor device according to an example embodiment. FIG. 22 to FIG. 28 illustrate a portion corresponding to FIG. 21.

As illustrated in FIG. 22, after forming a preliminary cell region and bonding the preliminary cell region to a circuit region, a thinning process may be performed. In the thinning process, portions of a semiconductor substrate 170p and a guide pattern 174 may be removed to expose the guide pattern 174 to an outside in a thickness direction or a vertical direction (a Z-axis direction in the drawings). Thereby, a first surface (an upper surface in FIG. 22) of the guide pattern 174 may be exposed to an outside. Description of some example embodiments and modified example embodiments with reference to FIG. 5 to FIG. 10 and FIG. 17 to FIG. 20 may be applied to the process of forming the preliminary cell region and the process of bonding the preliminary cell region to the circuit region.

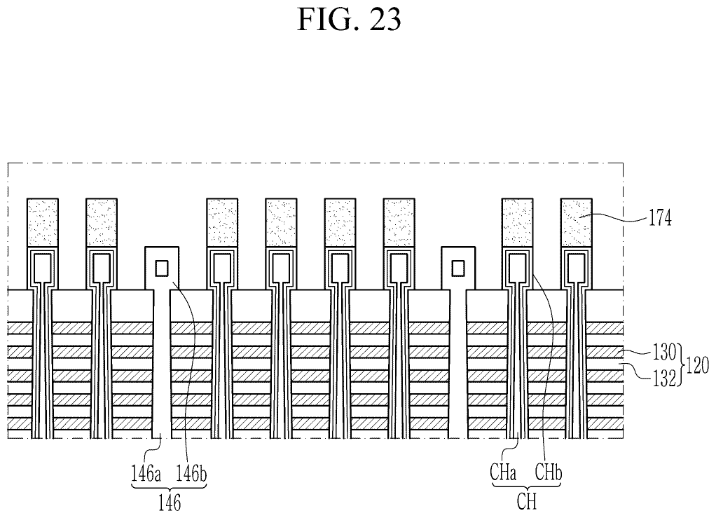

Subsequently, as illustrated in FIG. 23, the semiconductor substrate 170p (refer to FIG. 22) may be removed. For example, the semiconductor substrate 170p may be removed by an etching process of selectively etching the semiconductor substrate 170p. In the etching process, an etching material capable of etching the semiconductor substrate 170p more than a channel structure CH and the guide pattern 174 or etching the semiconductor substrate 170p without etching the channel structure CH and the guide pattern 174 may be used.

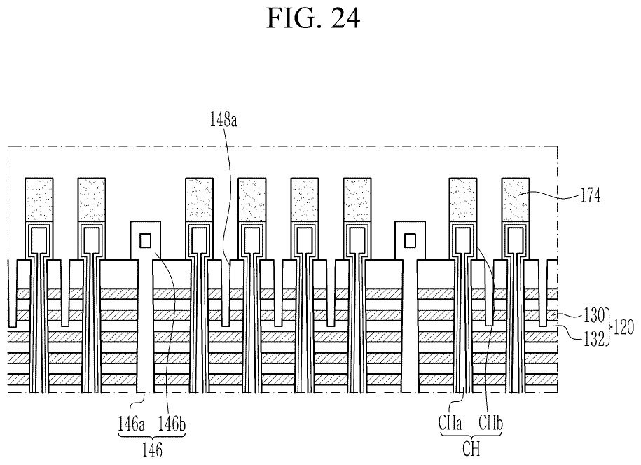

Subsequently, as illustrated in FIG. 24, an opening 148a for a separation pattern may be formed. The opening 148a for the separation pattern may pass through a portion of a gate stacking structure 120 (e.g., one or a part of a plurality of gate electrodes 130). The opening 148a for the separation pattern may be formed through an etching process of etching a portion of the gate stacking structure 120.

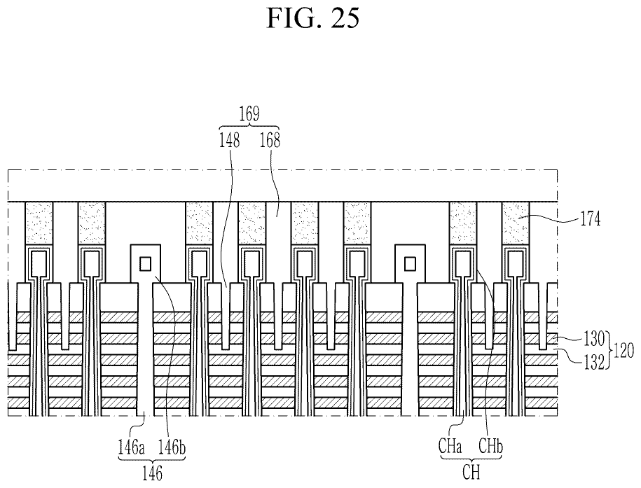

Subsequently, as illustrated in FIG. 25, a single insulation layer 169 may be formed to fill the opening 148a (refer to FIG. 24) for the separation pattern and a space between the plurality of channel structures CH and the plurality of guide patterns 174. That is, the single insulation layer 169 may include a separation pattern 148 and an intermediate insulation layer 168. Thereby, the separation pattern 148 and the intermediate insulation layer 168 may have an integral structure including a same material and connected to each other. The single insulation layer 169 may be formed by any of various processes (e.g., a deposition process or the like).

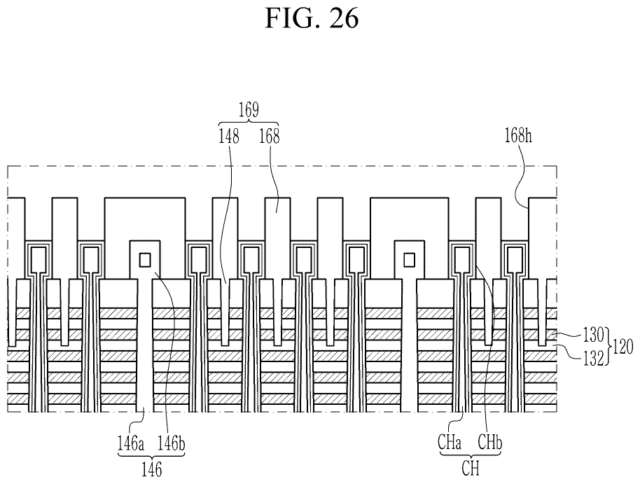

Subsequently, as illustrated in FIG. 26, the guide pattern 174 (refer to FIG. 25) may be selectively removed. For example, the guide pattern 174 may be selectively removed by an etching process. For example, in the etching process, an etching material capable of etching the guide pattern 174 more than the intermediate insulation layer 168 or etching the guide pattern 174 without etching the intermediate insulation layer 168. Thereby, a through hole 168h where the guide pattern 174 is removed may be formed in the intermediate insulation layer 168.

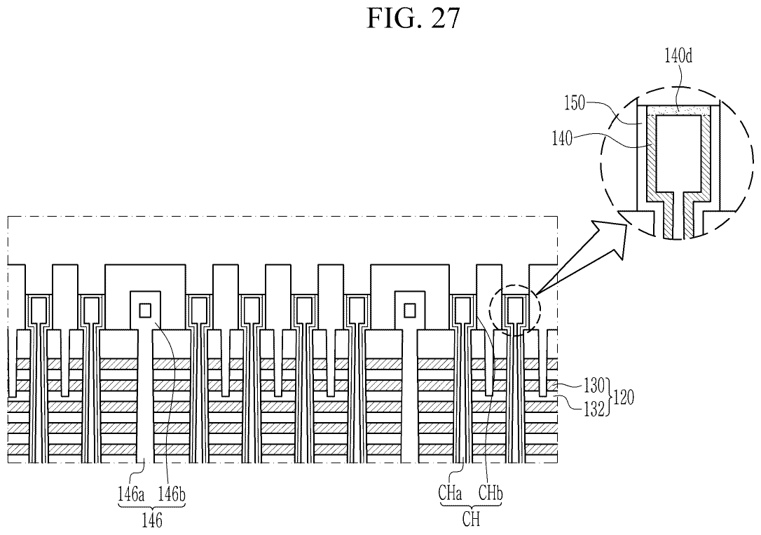

Subsequently, as illustrated in FIG. 27, a portion of a gate dielectric layer 150 in a first expanded portion CHb of the channel structure CH may be removed. A doping region 140d may be formed by doping a portion of the channel layer 140 exposed to an outside at an upper portion of the first expanded portion CHb of the channel structure CH.

The process of removing the portion of the gate dielectric layer 150 may be performed by any of various processes (e.g., an etching process or the like). The process of forming the doping region 140d may be performed by any of various processes (e.g., an ion implantation process or the like).

In some example embodiments, before, in, or after the process of removing the portion of the gate dielectric layer 150, a process of additionally removing a portion of the intermediate insulation layer 168 in the thickness direction or the vertical direction (the Z-axis direction in the drawings) may be performed. Thereby, a height of the through hole 168h may be adjusted. The process of additionally removing the portion of the intermediate insulation layer 168 may be performed by an etching process. However, example embodiments are not limited thereto, and the process of additionally removing the portion of the intermediate insulation layer 168 may be performed by any of various processes. In some example embodiments, the process of additionally removing the portion of the intermediate insulation layer 168 may be omitted.

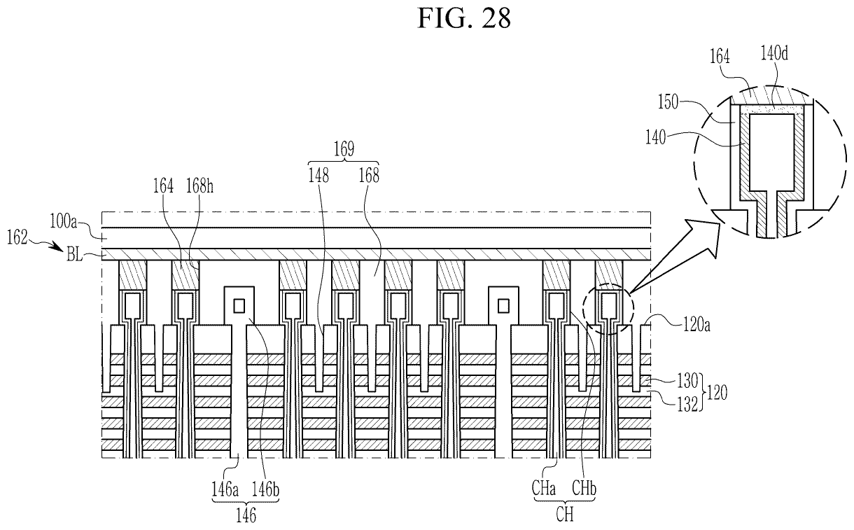

Subsequently, as illustrated in FIG. 28, a first wiring portion may be formed by forming a first contact portion 164 and a bit line BL. The process of forming the first contact portion 164 may be performed by any of various processes (e.g., a deposition process or the like). The process of forming the bit line BL may be performed by any of various processes (e.g., a deposition process or the like). Subsequently, an outer insulation layer 100a, an input/output contact portion, an input/output pad, or the like may be further formed.

In an example embodiment, the first contact portion 164 may be formed in the portion where the guide pattern 174 (refer to FIG. 25) is removed. Accordingly, the first contact portion 164 may be formed by a self-alignment.

According to an example embodiment, the first contact portion 164 (e.g., a bit line contact) may be formed by a self-alignment process using the guide pattern 174. Thereby, reliability and/or productivity of the semiconductor device may be improved. The plurality of first contact portions 164 may be disposed in the plurality of through holes 168h in the intermediate insulation layer 168, respectively, and the plurality of first expanded portions CHb of the plurality of channel structures CH may be disposed in the plurality of through holes 168h in the intermediate insulation layer 168, respectively. Thereby, undesirable defects (e.g., breakage of the first expanded portion CHb or the like) that may be induced in a manufacturing process may be reduced or prevented. The portion of the gate dielectric layer 150 in the first expanded portion CHb may be removed without removing an entire portion of the gate dielectric layer 150 in the first expanded portion CHb, thereby simplifying a manufacturing process and/or improving a stability. A process of forming a channel pad 144 (refer to FIG. 4) may be omitted and a manufacturing process may be simplified.

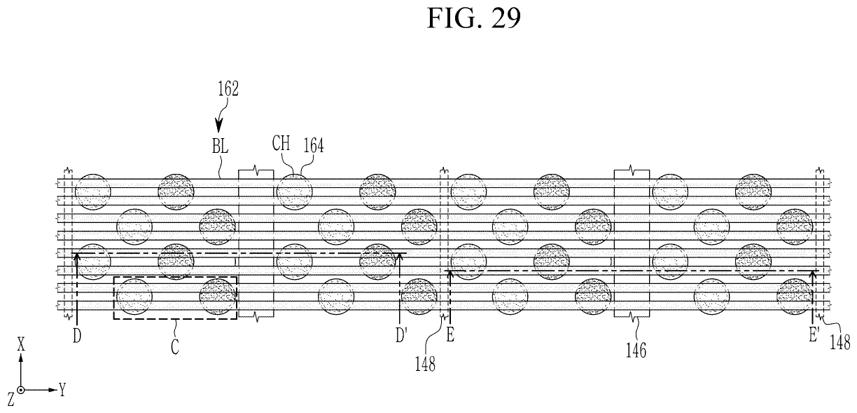

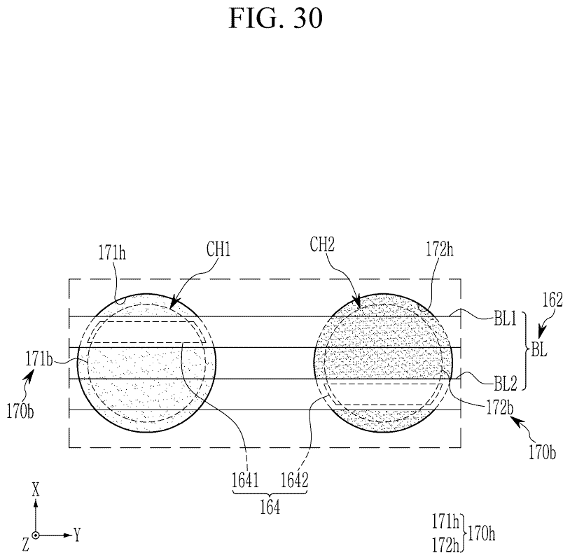

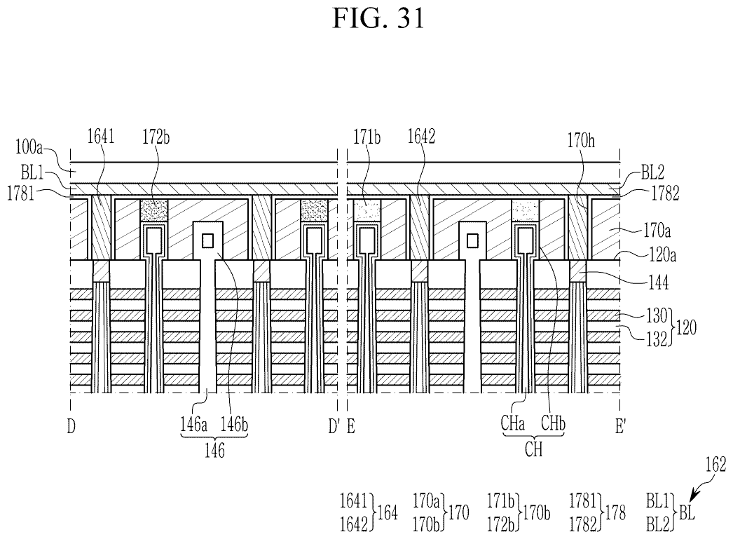

FIG. 29 is a plan view that schematically illustrates a semiconductor device according to an example embodiment. FIG. 30 is an enlarged plan view of a portion C in FIG. 29. FIG. 31 is a partial cross-sectional view taken along a line D-D′ and a line E-E′ in FIG. 29. FIG. 29 illustrates a portion corresponding to FIG. 3, and FIG. 31 illustrates a portion corresponding to FIG. 4. For a clear understanding, FIG. 29 mainly illustrates a channel structure CH, a first contact portion 164, a bit line BL, a separation structure 146, and a separation pattern 148. FIG. 30 illustrates a boundary of a bit line BL with respect to the bit line BL.

Referring to FIG. 29 to FIG. 31, in an example embodiment, in a plan view, a plurality of bit lines BL may overlap a channel structure CH. For example, a first bit line BL1 and a second bit line BL2 may be disposed to overlap the channel structure CH in a plan view, and the channel structure CH may be electrically connected to one of the first bit line BL1 and the second bit line BL2 through a first contact portion 164 (e.g., a bit line contact).

For example, the first bit line BL1 and the second bit line BL2 may be alternately electrically connected to a plurality of channel structures CH that are spaced apart from each other in a second direction (a Y-axis direction in the drawings). That is, in the second direction, a first channel structure CH1 and a second channel structure CH2 may be alternately disposed. The first channel structure CH1 may be electrically connected to the first bit line BL1 through the first contact portion 164 (e.g., a first bit line contact 1641). The second channel structure CH2 may be electrically connected to the second bit line BL2 through the first contact portion 164 (e.g., a second bit line contact 1642). A first insulation layer 166 (refer to FIG. 1) may be disposed between the first bit line BL1 and the second bit line BL2. For a clear understanding, in FIG. 29 and FIG. 30, the first insulation layer 166 disposed between the first bit line BL1 and the second bit line BL2 is omitted.

Between a first surface 120a of a gate stacking structure 120 and the first wiring 162 (e.g., at least between the first surface 120a of the gate stacking structure 120 and the bit line BL), an undoped semiconductor layer 170 may be disposed.

In an example embodiment, an intermediate layer may be disposed between the first surface 120a of the gate stacking structure 120 and the first wiring 162 (e.g., at least between the first surface 120a of the gate stacking structure 120 and the bit line BL). The intermediate layer may include a through hole 170h through which the first contact portion 164 pass. The first contact portion 164 may be partially disposed in a portion of the through hole 170h of the intermediate layer. The undoped semiconductor layer 170 may include a guide portion (e.g., a first guide portion 171b or a second guide portion 172b) that is partially disposed in a portion of the through hole 170h. For example, the guide portion may be disposed in a portion where the first contact portion 164 is not disposed in the through hole 170h.

For example, the undoped semiconductor layer 170 may include a first portion 170a and a second portion 170b. The first portion 170a may have a layered shape having the through hole 170h through which the first contact portion 164 passes. The second portion 170b may be disposed in a portion of the through hole 170h, and may include a material different from a material of the first portion 170a or may have a composition different from a composition of the first portion 170a. The intermediate layer having the through hole 170h may be the first portion 170a of the undoped semiconductor layer 170, and the guide portion may be the second portion 170b of the undoped semiconductor layer 170. However, example embodiments are not limited thereto, and the intermediate layer having the through hole 170h may be formed of a portion (e.g., an insulation layer) other than the first portion 170a of the undoped semiconductor layer 170. Various other example embodiments are possible.

The guide portion or the second portion 170b may include a first guide portion 171b and a second guide portion 172b. The first guide portion 171b may be disposed in a portion of a first through hole 171h that overlaps the first channel structure CH1, and the second guide portion 172b may be disposed in a portion of a second through hole 172h that overlaps the second channel structure CH2. The first guide portion 171b and the second guide portion 172b may include different materials or have different compositions.

The undoped semiconductor layer 170 may be electrically insulated from the first contact portion 164 and the bit line BL by a liner layer 178. In an example embodiment, the liner layer 178 may include a first liner layer 1781 and a second liner layer 1782. Terms of the first liner layer 1781 and the second liner layer 1782 may be used to discriminate between each other, but example embodiments are not limited thereto. Therefore, the first liner layer 1781 and the second liner layer 1782 may be formed by a same or similar process condition, or may include a same material.

For example, the first liner layer 1781 may include a side portion and a planar portion. The side portion of the first liner layer 1781 may be disposed between a side surface of the first portion 170a and a side surface of the first bit line contact 1641 and between a side surface of the first guide portion 171b and the first bit line contact 1641. The planar portion of the first liner layer 1781 may be disposed between an upper surface of the first portion 170a and a lower surface of the first wiring 162. For example, the second liner layer 1782 may include a side portion and a planar portion. The side portion of the second liner layer 1782 may be disposed between a side surface of the first portion 170a and a side surface of the second bit line contact 1642 and between a side surface of the second guide portion 172b and the second bit line contact 1642. The planar portion of the second liner layer 1782 may be disposed between an upper surface of the first portion 170a and a lower surface of the first wiring 162.

For example, the liner layer 178 (e.g., the first liner layer 1781 or the second liner layer 1782) may include or be formed of silicon oxide, silicon nitride, silicon oxynitride, a low dielectric constant material, or the like. However, example embodiments are not limited thereto, and a material of the liner layer 178 may be variously modified.

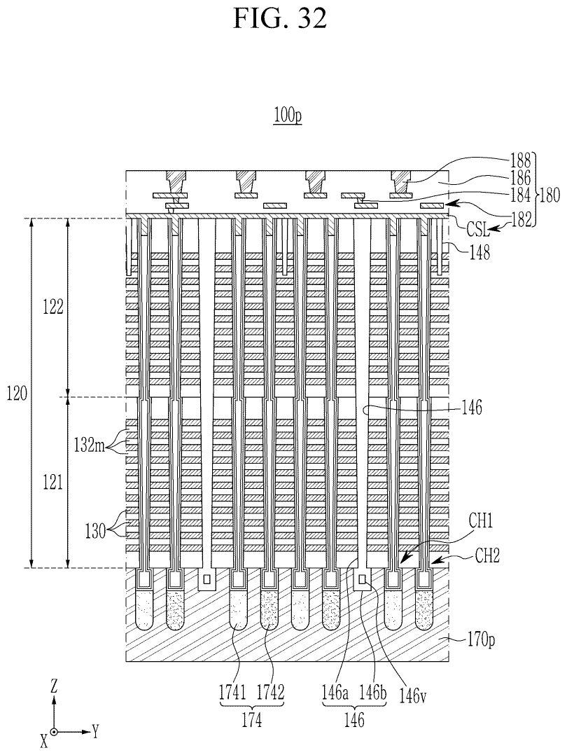

In an example embodiment, the first contact portion 164 may be formed through a self-alignment process using the undoped semiconductor layer 170 (e.g., the first portion 170a and/or the second portion 170b). In an example embodiment, the first guide portion 171b in the first through hole 171h or the second guide portion 172b in the second through hole 172h may be formed of a remainder of a portion of a guide pattern 174 (refer to FIG. 32) that is used in a manufacturing process of a semiconductor device.

The first through hole 171h may be disposed to correspond to or overlap the first channel structure CH1, and the first bit line contact 1641 that passes through the first guide portion 171b and electrically connects the first bit line BL1 and the first channel structure CH1 may be disposed in the first through hole 171h. In a plan view, the first bit line contact 1641 may pass through the first guide portion 171b in a portion where the first bit line BL1 overlaps, and the first guide portion 171b may be disposed in a portion where the first bit line BL1 does not overlap. That is, the first bit line contact 1641 may be partially disposed in a portion of the first through hole 171h, and the first guide portion 171b may be partially disposed in another portion of the first through hole 171h.

The second through hole 172h may be disposed to correspond to or overlap the second channel structure CH2, and the second bit line contact 1642 that passes through the second guide portion 172b and electrically connects the second bit line BL2 and the second channel structure CH2 may be disposed in the second through hole 172h. In a plan view, the second bit line contact 1642 may pass through the second guide portion 172b in a portion where the second bit line BL2 overlaps, and the second guide portion 172b may be disposed in a portion where the second bit line BL2 does not overlap. That is, the second bit line contact 1642 may be partially disposed in a portion of the second through hole 172h, and the second guide portion 172b may be partially disposed in another portion of the second through hole 172h.

In an example embodiment, the second portion 170b may include a material different from a material of the first portion 170a or may have a composition different from a composition of the first portion 170a. The first guide portion 171b and the second guide portion 172b may include different materials or have different compositions. For example, the first guide portion 171b and the second guide portion 172b may include a same semiconductor material and may have different compositions.

For example, the first portion 170a may include undoped silicon, and the first guide portion 171b and the second guide portion 172b may include undoped silicon-germanium. An amount of germanium in the first guide portion 171b and an amount of germanium in the second guide portion 172b may be different from each other. That is, the first guide portion 171b may include a first silicon-germanium layer having a first germanium amount, and the second guide portion 172b may include a second silicon-germanium layer having a second germanium amount less than the first germanium amount.

In an example embodiment, the first bit line contact 1641 or the second bit line contact 1642 may be easily selectively connected to one of the first bit line BL1 and the second bit line BL2 by using the first guide portion 171b and the second guide portion 172b including different materials or having different compositions. Thereby, a number of a mask used in the manufacturing method of the semiconductor device may be reduced and productivity may be improved.

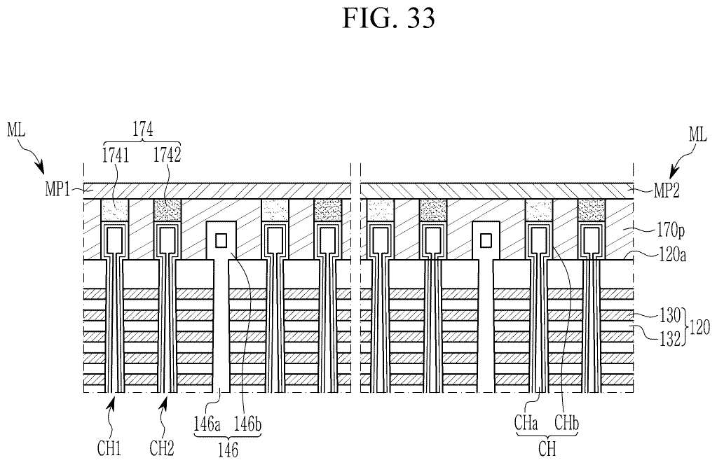

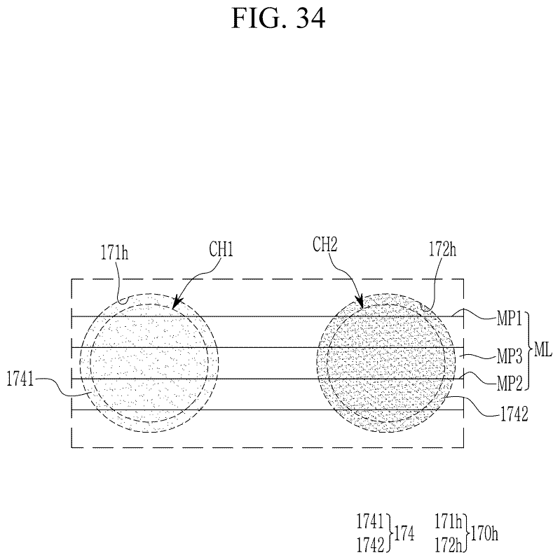

FIG. 32 to FIG. 38 illustrate a manufacturing method of a semiconductor device according to an example embodiment. FIG. 32 illustrates a portion corresponding to a cell array region 102 in FIG. 1, and FIG. 33 and FIG. 35 to FIG. 38 illustrate a portion corresponding to FIG. 31. FIG. 34 illustrates a portion corresponding to FIG. 30.

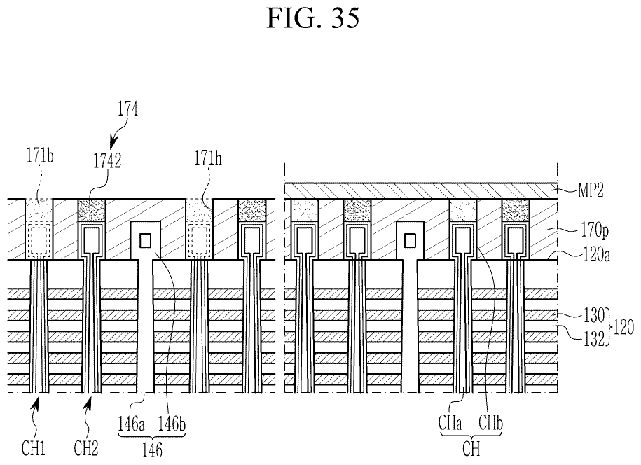

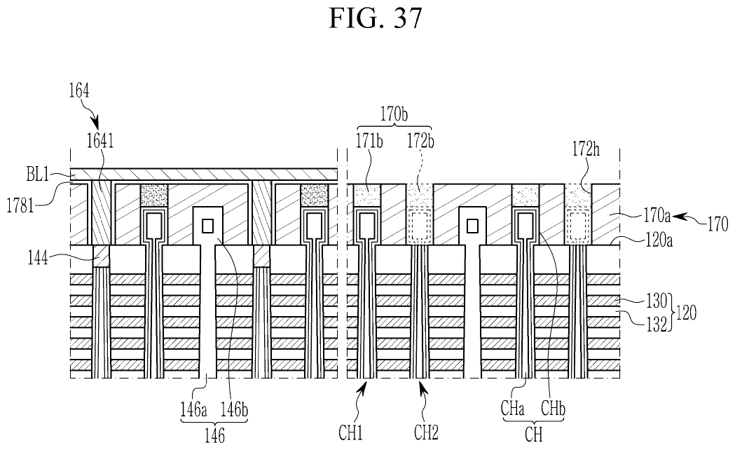

As illustrated in FIG. 32, a guide pattern 174 that is disposed in a semiconductor substrate 170p in a preliminary cell region 100p may include a first guide pattern 1741 and a second guide pattern 1742. The first guide pattern 1741 may be disposed to correspond to a first channel structure CH1, and the second guide pattern 1742 may be disposed to correspond to a second channel structure CH2. Each of the first guide pattern 1741 and the second guide pattern 1742 may include a material different from a material of the semiconductor substrate 170p or has a composition different from a composition of the semiconductor substrate 170p, and the first guide pattern 1741 and the second guide pattern 1742 may include different materials or have different compositions. In a subsequent process, a portion of the first guide pattern 1741 may remain to form a first guide portion 171b (refer to FIG. 35), and a portion of the second guide pattern 1742 may remain to form a second guide portion 172b (refer to FIG. 37)

For example, the semiconductor substrate 170p may include undoped silicon, and the first guide pattern 1741 and the second guide pattern 1742 may include undoped silicon-germanium. An amount of germanium in the first guide pattern 171 and an amount of germanium in the second guide pattern 172 may be different from each other. That is, the first guide pattern 171 may include a first silicon-germanium layer having a first germanium amount, and the second guide pattern 172 may include a second silicon-germanium layer having a second germanium amount less than the first germanium amount. However, example embodiments are not limited thereto, and the semiconductor substrate 170p and/or the guide pattern 174 may include any of various materials.

A description with reference to FIG. 5 to FIG. 9 may be applied to a portion other than the first guide pattern 1741 and the second guide pattern 1742.

Subsequently, as illustrated in FIG. 33, after forming a preliminary cell region 100p (refer to FIG. 32) and bonding the preliminary cell region 100p to a circuit region, a thinning process may be performed. In the thinning process, portions of the semiconductor substrate 170p and the guide pattern 174 may be removed to expose the guide pattern 174 to an outside in a thickness direction or a vertical direction (a Z-axis direction in the drawings). Thereby, a first surface (an upper surface in FIG. 33) of the guide pattern 174 may be exposed to an outside. A description with reference to FIG. 10 and FIG. 11 may be applied.

Subsequently, a mask layer ML may be formed on the semiconductor substrate 170p and the guide pattern 174. A shape of the mask layer ML will be described with reference to FIG. 34. FIG. 34 illustrates boundaries of first to third mask patterns MP1, MP2, and MP3 with respect to the first to third mask patterns MP1, MP2, and MP3.

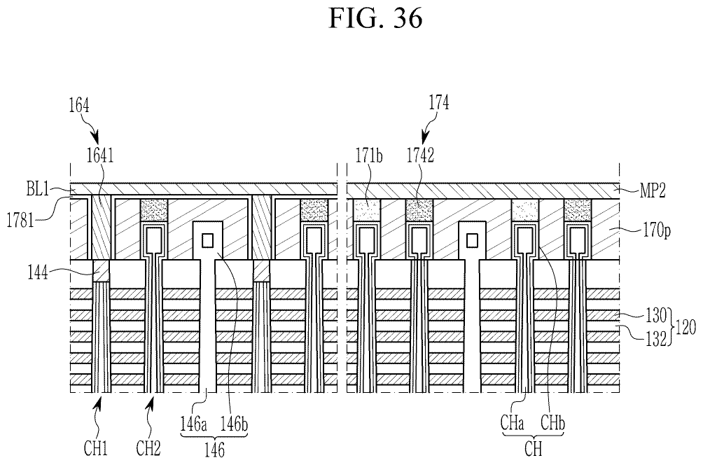

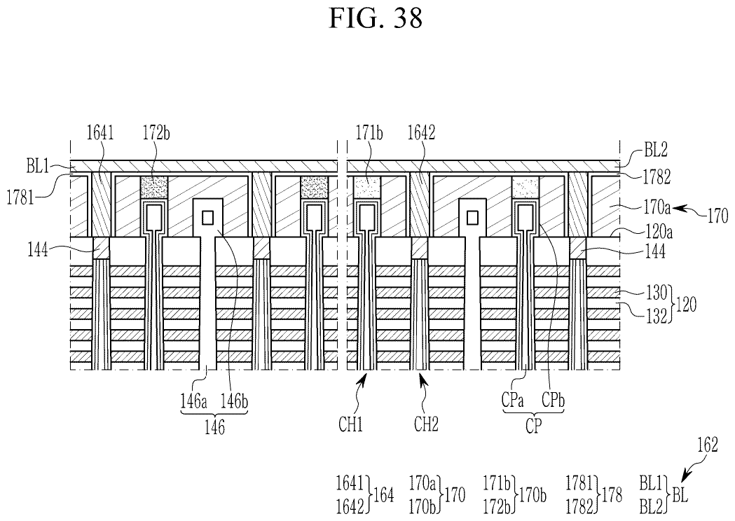

As illustrated in FIG. 34, the mask layer ML may include a first mask pattern MP1 and a second mask pattern MP2, and may further include a third mask pattern MP3. The first mask pattern MP1 may be disposed to correspond to a portion where a first bit line BL1 (refer to FIG. 36) will be disposed. The second mask pattern MP2 may be disposed to correspond to a portion where a second bit line BL2 (refer to FIG. 38) will be disposed. The third mask pattern MP3 may be disposed between the first mask pattern MP1 and the second mask pattern MP2. Each of the first mask pattern MP1 and the second mask pattern MP2 may include a material different from a material of the third mask pattern MP3 or may have a composition different from a composition of the third mask pattern MP3. The first mask pattern MP1 and the second mask pattern MP2 may include different materials or have different compositions.

For example, the first mask pattern MP1 and the second mask pattern MP2 may be a photoresist pattern or a hard mask, and the third mask pattern MP3 may include or be formed of an insulating material. When the third mask pattern MP3 includes the insulating material, the third mask pattern MP3 may remain to form a first insulation layer of a first wiring portion. In some example embodiments, the third mask pattern MP3 may be removed in a subsequent process, and the first insulation layer of the first wiring portion may be formed by a separate process. However, example embodiments are not limited thereto, and the first to third mask patterns MP1, MP2, and MP3 may include any of various materials.

The mask layer ML that includes the first to third mask patterns MP1, MP2, and MP3 may be formed by any of various processes using double patterning or multi patterning.

Subsequently, as illustrated in FIG. 35, the first mask pattern MP1 (refer to FIG. 33) may be removed, and a portion of the first guide pattern 1741 (refer to FIG. 33) and a portion of the first expanded portion CHb of the first channel structure CH1 exposed to an outside may be removed. The portion of the first guide pattern 1741 may be exposed to the outside by removing the first mask pattern MP1 and the portion of the first expanded portion CHb of the first channel structure CH1 may be disposed under the portion of the first guide pattern 1741. Thereby, the first guide portion 171b having a first contact hole in a portion corresponding to a first bit line BL1 (refer to FIG. 36) may be formed.

For a clear understanding, in FIG. 35, another portion of the first guide pattern 1741 and another portion of the first expanded portion CHb of the first channel structure CH1 remained in the first through hole 171h are illustrated as a dotted line in a first through hole 171h.

The process of removing the portion of the first guide pattern 1741 and the portion of the first expanded portion CHb of the first channel structure CH1 exposed to the outside may be performed by any of various processes (e.g., an etching process). In the etching process, the portion of the first guide pattern 1741 may be selectively removed using an etching material capable of etching the first guide pattern 1741 more than the second guide pattern 1742 and the semiconductor substrate 170p or etching the first guide pattern 1741 without etching the second guide pattern 1742 and the semiconductor substrate 170p. Thereby, the second guide pattern 1742 that is exposed to an outside by removing the first mask pattern MP1 may not be removed and may remain. After selectively removing the portion of the first guide pattern 1741, the portion of the first expanded portion CHb of the first channel structure CH1 under the first guide pattern 1741 may be selectively removed using an etching material capable of selectively removing the portion of the first expanded portion CHb of the first channel structure CH1.

Subsequently, as illustrated in FIG. 36, a first liner layer 1781 may be formed on an inner side surface of the first guide portion 171b, an inner side surface of the first through hole 171h, an upper surface of the semiconductor substrate 170p, and/or an upper surface of the second guide pattern 1742. Subsequently, a channel pad 144 of the first channel structure CH1 may be formed, a first bit line contact 1641 may be formed, and a first bit line BL1 may be formed in a portion where the first mask pattern MP1 (refer to FIG. 33) was disposed and has been removed. The first bit line contact 1641 may be formed in a first contact hole that passes through the first guide portion 171b, and the first bit line BL1 may be formed to be electrically connected to the first bit line contact 1641.

The process of forming the first liner layer 1781 may be performed by any of various processes (e.g., a deposition process or the like). A description with reference to FIG. 14 may be applied to the process of forming the channel pad 144, and a description of a process of forming a first contact portion 164 with reference to FIG. 15 may be applied to the process of forming the first bit line contact 1641. The process of forming the first bit line BL1 may be performed by any of various processes (e.g., a deposition process or the like).

Subsequently, as illustrated in FIG. 37, the second mask pattern MP2 (refer to FIG. 36) may be removed, and a portion of the second guide pattern 1742 (refer to FIG. 36) and a portion of the first expanded portion CHb of the second channel structure CH2 exposed to an outside may be removed. The portion of the second guide pattern 1742 may be exposed to the outside by removing the second mask pattern MP2 and the portion of the first expanded portion CHb of the second channel structure CH2 may be disposed under the portion of the second guide pattern 1742. Thereby, the second guide portion 172b having a second contact hole in a portion corresponding to a second bit line BL2 (refer to FIG. 38) may be formed.

For a clear understanding, in FIG. 37, another portion of the second guide pattern 1742 and another portion of the first expanded portion CHb of the second channel structure CH2 remained in the second through hole 172h are illustrated as a dotted line in a second through hole 172h.

The process of removing the portion of the second guide pattern 1742 and the portion of the first expanded portion CHb of the second channel structure CH2 may be performed by any of various processes (e.g., an etching process). In the etching process, the portion of the second guide pattern 1742 may be selectively removed using an etching material capable of etching the second guide pattern 1742 more than the first guide pattern 1741 and the semiconductor substrate 170p or etching the second guide pattern 1742 without etching the first guide pattern 1741 and the semiconductor substrate 170p. Thereby, the first guide pattern 1741 that is exposed to an outside by removing the second mask pattern MP2 may not be removed and may remain. After selectively removing the portion of the first guide pattern 1741, the portion of the first expanded portion CHb of the second channel structure CH2 under the second guide pattern 1742 may be selectively removed using an etching material capable of selectively removing the portion of the first expanded portion CHb of the second channel structure CH2.

A portion of the semiconductor substrate 170p (refer to FIG. 36) remaining after the first through hole 171h and the second through hole 172h are formed may form a undoped semiconductor layer 170 (e.g., a first portion 170a).

Subsequently, as illustrated in FIG. 38, a second liner layer 1782 may be formed on an inner side surface of the second guide portion 172b, an inner side surface of the second through hole 172h, an upper surface of the semiconductor substrate 170p, and/or an upper surface of the first guide pattern 1741. Subsequently, a channel pad 144 of the second channel structure CH2 may be formed, a second bit line contact 1642 may be formed, and a second bit line BL2 may be formed in a portion where the second mask pattern MP2 (refer to FIG. 36) was disposed and has been removed. The second bit line contact 1642 may be formed in a second contact hole that passes through the second guide portion 172b, and the second bit line BL2 may be formed to be electrically connected to the second bit line contact 1642.

The process of forming the second liner layer 1782 may be performed by any of various processes (e.g., a deposition process or the like). A description with reference to FIG. 14 may be applied to the process of forming the channel pad 144, and a description of a process of forming a first contact portion 164 with reference to FIG. 15 may be applied to the process of forming the second bit line contact 1642. The process of forming the second bit line BL2 may be performed by any of various processes (e.g., a deposition process or the like).

Subsequently, an outer insulation layer, an input/output contact portion, an input/output pad, or the like may be further formed.

In the description, it is described as an example that, after a portion of the first guide pattern 1741 having a relatively high germanium amount is removed, a portion of the second guide pattern 1742 having a relatively low germanium amount is removed. Thereby, a stability may be improved. However, example embodiments are not limited thereto. In some example embodiments, after the portion of the second guide pattern 1742 having the relatively low germanium amount is removed, the portion of the first guide pattern 1741 having the relatively high germanium amount may be removed. Various other example embodiments are possible.

In an example embodiment, the first bit line contact 1641 passing through the first guide portion 171b and the second bit line contact 1642 passing through the second guide portion 172b may be formed using the mask layer ML including the first to third mask patterns MP1, MP2, and MP3. Thereby, a number of a mask may be reduced and a manufacturing process may be simplified. However, example embodiments are not limited thereto. In some example embodiments, the first bit line contact 1641 passing through the first guide portion 171b and the second bit line contact 1642 passing through the second guide portion 172b may be formed by sequentially using a first mask layer and a second mask layer. The first mask layer may have a first opening that exposes a portion where the first bit line contact 1641 is to be formed, and the second mask layer may have a second opening that exposes a portion where the second bit line contact 1642 is to be formed. Various other example embodiments are possible.

According to an example embodiment, the first contact portion 164 (e.g., a bit line contact) may be formed by a self-alignment process using the guide pattern 174. Thereby, reliability and/or productivity of a semiconductor device may be improved. By using the mask layer ML including the first mask pattern MP1 and the second mask pattern MP2, and the first guide pattern 1741 and the second guide pattern 1742 including different material or having different composition, a manufacturing method of a semiconductor device including the first bit line BL1 and the second bit line BL2 may be simplified and/or production cost may be reduced.

An example of an electronic system including a semiconductor device will be described in detail below.

FIG. 39 is a view that schematically illustrates an electronic system including a semiconductor device according to an example embodiment.

Referring to FIG. 39, an electronic system 1000 according to an example embodiment may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 38. The semiconductor device 1100 may include a first structure 1100F and a second structure 1100S that is disposed on the first structure 1100F. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an example embodiment.

In an example embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some example embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to desired (or alternatively, predetermined) firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

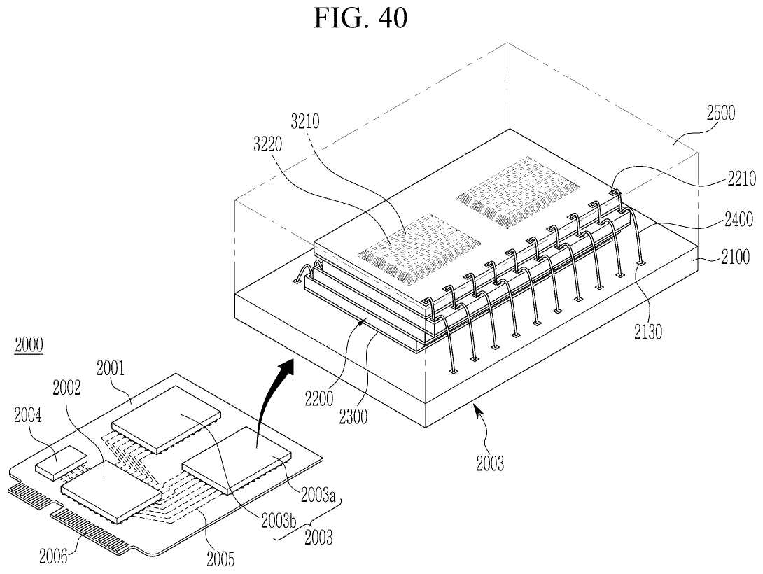

FIG. 40 is a perspective view that schematically illustrates an electronic system including a semiconductor device according to an example embodiment.

Referring to FIG. 40, an electronic system 2000 according to an example embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an example embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an example embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package that includes a plurality of semiconductor chips 2200. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 39. Each semiconductor chip 2200 may include a gate stacking structure 3210 and a channel structure 3220. The semiconductor chip 2200 may include a semiconductor device described with reference to FIG. 1 to FIG. 38.

In an example embodiment, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100. According to an example embodiment, in each of the first and second semiconductor packages 2003a and 2003b, the semiconductor chips 2200 may be electrically connected to each other by a connection structure that includes a through silicon via (TSV) instead of the connection structure 2400 of the bonding wire type.

In an example embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 41 is a cross-sectional view that schematically illustrates a semiconductor package according to an example embodiment. FIG. 41 illustrates an example embodiment of the semiconductor package 2003 illustrated in FIG. 40, and conceptually illustrates a region obtained by cutting the semiconductor package 2003 of FIG. 40 along a line I-I′.

Referring to FIG. 41, in the semiconductor package 2003, the package substrate 2100 may be a printed circuit board. The package substrate 2100 may include a package substrate body portion 2120, a package upper pad 2130 disposed at an upper surface of the package substrate body portion 2120, a package lower pad 2125 disposed at a lower surface of the package substrate body portion 2120 or exposed through the lower surface of the package substrate body portion 2120, and an internal wiring 2135 electrically connecting the package upper pad 2130 and the package lower pad 2125 inside the package substrate body portion 2120. The package upper pad 2130 may be electrically connected to the connection structure 2400. The package lower pad 2125 may be connected to a wiring pattern 2005 of the main substrate 2001 of the electronic system 2000, as illustrated in FIG. 40, through a conductive connection portion 2800.

In a semiconductor package 2003, each semiconductor chip 2200 may include a semiconductor substrate 4010, a first structure 4100 on the semiconductor substrate 4010, and a second structure 4200 disposed on the first structure 4100 and bonded to the first structure 4100 by a wafer bonding type.

The first structure 4100 may include a peripheral circuit region including a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 passing through the gate stacking structure 4210, and a second bonding structure 4250 electrically connected to the channel structure 4220 and a word line WL (refer to FIG. 39) of the gate stacking structure 4210. For example, the second bonding structure 4250 may be electrically connected to the channel structure 4220 and the word line WL through a wiring portion 4240 including a bit line electrically connected to the channel structure 4220 and a gate connection wiring electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In the semiconductor chip 2200 or the semiconductor device according to an example embodiment, a bit line contact may be formed by a self-alignment process using a guide pattern. Thereby, reliability and/or productivity of the semiconductor device may be improved.

Each of the semiconductor chips 2200 may further include an input/output pad 2210 and an input/output connection wiring 4265 at a lower portion of the input/output pad 2210. The input/output connection wiring 4265 may be electrically connected to a part of the second bonding structure 4250.

In an example embodiment, in the semiconductor package 2003, a plurality of semiconductor chips 2200 may be electrically connected to each other by the connection structure 2400 having a bonding wire type. In some example embodiments, the plurality of semiconductor chips 2200 or a plurality of portions constituting the plurality of semiconductor chips 2200 may be electrically connected by a connection structure including a through silicon via (TSV).

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some examples have been described in connection with what is presently considered to be some practical example embodiments, it is to be understood that the disclosure is not limited to the disclosed example embodiments, and that that the disclosure is intended to cover various modifications and equivalent arrangements included within the spirit and scope of the appended claims.

1. A semiconductor device, comprising:
a gate stacking structure including a first surface and a second surface that are opposite to each other, the gate stacking structure including a plurality of interlayer insulation layers and a plurality of gate electrodes alternating on each other;
a channel structure extending through the gate stacking structure;
a wiring on the first surface of the gate stacking structure;
an undoped semiconductor layer between the first surface of the gate stacking structure and the wiring; and
a contact portion passing through the undoped semiconductor layer and electrically connecting the channel structure and the wiring.

2. The semiconductor device of claim 1, further comprising:
a liner layer configured to electrically insulate the undoped semiconductor layer from the contact portion and the wiring.

3. The semiconductor device of claim 1, wherein
the contact portion is directly connected to the wiring, and
a width of the contact portion is greater than a width of the wiring.

4. The semiconductor device of claim 1, wherein
the undoped semiconductor layer includes a first portion, and
the first portion has a through hole through which the contact portion extends vertically and overlaps the channel structure in a plan view.

5. The semiconductor device of claim 4, wherein
the channel structure includes a plurality of channel structures spaced apart from each other,
the through hole includes a plurality of through holes corresponding to the plurality of channel structures, respectively, and
the first portion has a layered shape connected in portions other than the plurality of through holes.

6. The semiconductor device of claim 4, further comprising:
a separation structure passing through the gate stacking structure and dividing the gate stacking structure in a plan view,
wherein the separation structure includes a penetration portion and an expanded portion,
wherein the penetration portion extends through the gate stacking structure, and
wherein the expanded portion is on the first surface of the gate stacking structure and has a width or an area greater than a width or an area of the penetration portion.

7. The semiconductor device of claim 6, wherein a height of the contact portion is greater than a height of the expanded portion.

8. The semiconductor device of claim 4, wherein a width or an area of the contact portion is greater than a width or an area of the channel structure.

9. The semiconductor device of claim 1, further comprising:
an intermediate layer including a through hole through which the contact portion passes,
wherein the undoped semiconductor layer includes a guide portion that is in a portion of the through hole.

10. The semiconductor device of claim 1, wherein
the undoped semiconductor layer includes a first portion and a second portion,
the first portion includes a through hole through which the contact portion passes,
the second portion is in a portion of the through hole, and
the second portion includes a material different from a material of the first portion or has a composition different from a composition of the first portion.

11. The semiconductor device of claim 1, wherein
the wiring includes a first bit line and a second bit line that overlap the channel structure in a plan view,
the channel structure includes a first channel structure and a second channel structure, the first channel structure electrically connected to the first bit line, the second channel structure electrically connected to the second bit line,
the contact portion includes a first bit line contact and a second bit line contact,
wherein the first bit line contact is electrically connected to the first channel structure and the first bit line in a portion of a first through hole corresponding to the first channel structure,
wherein the second bit line contact is electrically connected to the second channel structure and the second bit line in a portion of a second through hole corresponding to the second channel structure,
the undoped semiconductor layer includes a first guide portion and a second guide portion,
the first guide portion is in another portion of the first through hole, and
the second guide portion is in another portion of the second through hole.

12. The semiconductor device of claim 11, wherein the first guide portion and the second guide portion include different materials or have different compositions.

13. The semiconductor device of claim 1, wherein the wiring includes a bit line, and the contact portion includes a bit line contact.

14. The semiconductor device of claim 1, further comprising:
a circuit region electrically connected to a cell region, the cell region including the gate stacking structure, the channel structure, the wiring, the undoped semiconductor layer, and the contact portion; and
a common source electrode being adjacent to the second surface of the gate stacking structure that faces the circuit region and electrically connected to the channel structure.

15. A semiconductor device, comprising:
a gate stacking structure including a first surface and a second surface that are opposite to each other, the gate stacking structure including a plurality of interlayer insulation layers and a plurality of gate electrodes alternating on each other;
a channel structure including a penetration portion and an expanded portion, the penetration portion extending through the gate stacking structure, the expanded portion being on the first surface of the gate stacking structure and having a width or an area greater than a width or an area of the penetration portion;
a wiring on the first surface of the gate stacking structure; and
a contact portion corresponding to the channel structure and electrically connecting the channel structure and the wiring, the contact portion having a width or an area greater than a width or an area of the penetration portion of the channel structure.

16. The semiconductor device of claim 15, wherein
the contact portion is directly connected to the wiring, and a width of the contact portion is greater than a width of the wiring; or
the contact portion includes a portion that has a width or an area substantially same as a width or an area of the expanded portion of the channel structure.

17. The semiconductor device of claim 15, wherein
the channel structure including a channel layer and a gate dielectric layer between the plurality of gate electrodes and the channel layer,
a portion of the channel layer in an upper portion of the expanded portion includes a doping region, and
the contact portion is electrically connected to the doping region.

18. The semiconductor device of claim 15, further comprising:
an intermediate insulation layer between the first surface of the gate stacking structure and the wiring, the intermediate insulation layer including a penetration part through which the expanded portion and the contact portion pass, and
a side surface of the expanded portion and a side surface of the contact portion are on a same plane.

19. The semiconductor device of claim 15, further comprising:
an intermediate insulation layer between the first surface of the gate stacking structure and the wiring, the intermediate insulation layer including a penetration part through which the expanded portion and the contact portion pass; and
a separation pattern adjacent to the first surface of the gate stacking structure,
wherein the intermediate insulation layer and the separation pattern include a same material and have an integral structure.

20. An electronic system, comprising:
a main substrate;
a semiconductor device on the main substrate; and
a controller electrically connected to the semiconductor device on the main substrate,
wherein the semiconductor device comprises
a gate stacking structure including a first surface and a second surface that are opposite to each other, the gate stacking structure including a plurality of interlayer insulation layers and a plurality of gate electrodes alternating on each other,
a channel structure extending through the gate stacking structure,
a wiring on the first surface of the gate stacking structure,
an undoped semiconductor layer between the first surface of the gate stacking structure and the wiring, and
a contact portion passing through the undoped semiconductor layer and electrically connecting the channel structure and the wiring.

21.-35. (canceled)
